(19) United States
(12) Patent Application Publication
(10) Pub. No.: US 2025/0246326 A1
(43) Pub. Date: Jul. 31, 2025

(54) Optimizing the Detector Placement for the Nuclear Reactor Core software using Reinforcement Learning

(71) Applicant: Georgia Tech Research Corporation, Atlanta, GA (US)

(72) Inventors: Fan Zhang, Atlanta, GA (US); Kai Tan, Atlanta, GA (US)

(21) Appl. No.: 19/042,355

(22) Filed: Jan. 31, 2025

Related U.S. Application Data
(60) Provisional application No. 63/627,454, filed on Jan. 31, 2024.

(51) Int. Cl. G21D 3/00; G21C 17/108

(52) U.S. Cl. CPC G21D 3/002; G21C 17/108

(57) ABSTRACT

An exemplary system and method provide nuclear reactors with optimized detector placement. The exemplary system and method include a nuclear reactor model, Markov decision process, and reward function, where reinforcement learning can be used to iteratively generate placements of detectors to candidate positions within the nuclear reactor.

### CROSS REFERENCE TO RELATED APPLICATIONS

This application claims priority to and benefit of U.S. Provisional Patent Application Ser. No. 63/627,454 entitled “OPTIMIZING THE DETECTOR PLACEMENT FOR THE NUCLEAR REACTOR CORE SOFTWARE USING FOUR REINFORCEMENT LEARNING” filed Jan. 31, 2024, which is hereby incorporated by reference herein in its entirety as if fully set forth below.

### BACKGROUND

Nuclear reactors generate energy using radiation. The radiation can heat water to create steam, and the expanding steam can then be used to drive turbines to produce electrical power. The radiation inside a nuclear reactor is generated by the decay of fissile materials (e.g., uranium) and that radioactive decay can be controlled using control rods and other features of a nuclear reactor. Detectors are used to monitor the radioactive decay and allow operators and control systems to make control decisions for safe and efficient operation of the nuclear reactor.

There is a benefit to improving the positioning of detectors in nuclear reactors.

### SUMMARY

An exemplary system and method is disclosed that applies reinforcement learning (RL) techniques to 3D flux distribution models of nuclear reactor cores. Flux monitoring can benefit the safety and economics of nuclear reactors, and is often achieved by strategically-placed in-core detectors. However, the deployment of these sensors is often constrained by physical, industrial, and economic limitations. Implementations of the present disclosure can improve the design of nuclear reactors by modeling these and other limitations of nuclear reactor design and identifying optimized sensor locations.

The example implementations described herein can be used to optimize the location of in-core detectors by creating a Markov Decision Process and using RL to provide a solution for detector placement given a fixed number of detector and available detector positions. An example RL-based method includes a Proper Orthogonal Decomposition (POD) based power reconstruction function paired with a reward function based on the power reconstruction error and a well-educated agent that updates the detector placement. Four example RL algorithms that can be used include Proximal Policy Optimization, Deep Q-Network (DQN), Advantage Actor-Critic (A2C), and Monte Carlo Tree Search (MCTS).

The example implementations were compared with the Genetic Algorithm. As described herein, the flexible nature of RL enables the integration of developed novel reward functions from a specific reactor core into other reactors, considering the particular engineering requirements within the RL-based framework, thereby enhancing the optimization of in-core detector configurations. The systems and methods described herein can be used in light water reactors and other advanced reactor core detector placement optimization.

In some aspects, implementations of the present disclosure include a computer-implemented method for optimizing nuclear reactor detector placement, the method including: receiving a nuclear reactor model, wherein the nuclear reactor model includes a model of (i) at least one radiation source or flux and (ii) a plurality of candidate detector positions; constructing a Markov Decision Process (MDP) wherein the MDP includes a process for selecting detector placements and comparing simulated flux distribution and a reconstructed flux distribution for simulated detector placements; determining a reward function, wherein the reward function is configured to evaluate a power reconstruction error between the simulated flux distribution and the reconstructed flux distribution; selecting a first arrangement of detectors based on the MDP and performing a first evaluation of the first arrangement of detectors by the reward function; selecting a second arrangement of detectors based on the MDP and performing a second evaluation of the second arrangement of detectors by the reward function; determining an optimized configuration of detectors for the nuclear reactor model based on the first evaluation and the second evaluation, wherein the optimized configuration of detectors includes an assignment of detectors to at least one of the plurality of candidate detector positions.

In some aspects, implementations of the present disclosure include a computer-implemented method, wherein determining an optimized configuration of detectors includes iteratively selecting a plurality of detector placements.

In some aspects, implementations of the present disclosure include a computer-implemented method, wherein determining the optimized configuration of detectors includes applying a reinforcement learning (RL) algorithm.

In some aspects, implementations of the present disclosure include a computer-implemented method, wherein the RL includes Proper Orthogonal Decomposition (POD) based power reconstruction function paired with a reward function based on the power reconstruction error.

In some aspects, implementations of the present disclosure include a computer-implemented method, wherein the RL includes at least one of Proximal Policy Optimization, Deep Q-Network (DQN), Advantage Actor-Critic (A2C), and Monte Carlo Tree Search (MCTS).

In some aspects, implementations of the present disclosure include a computer-implemented method, wherein the second detector placement is determined by a trained agent configured to update the detector placement.

In some aspects, implementations of the present disclosure include a computer-implemented method, wherein the nuclear reactor model includes a model of a pressurized water reactor (PWR).

In some aspects, implementations of the present disclosure include a non-transitory computer readable medium having instructions stored thereon, wherein execution of the instructions by a processor, causes the processor to: receive a nuclear reactor model, wherein the nuclear reactor model includes a model of (i) at least one radiation source or flux and (ii) a plurality of candidate detector positions; construct a Markov Decision Process (MDP) wherein the MDP includes a process for selecting detector placements and comparing simulated flux distribution and a reconstructed flux distribution for simulated detector placements; determine a reward function, wherein the reward function is configured to evaluate a power reconstruction error between the simulated flux distribution and the reconstructed flux distribution; select a first arrangement of detectors based on the MDP and performing a first evaluation of the first arrangement of detectors by the reward function; select a second arrangement of detectors based on the MDP and performing a second evaluation of the second arrangement of detectors by the reward function; determine an optimized configuration of detectors for the nuclear reactor model based on the first evaluation and the second evaluation, wherein the optimized configuration of detectors includes an assignment of detectors to at least one of the plurality of candidate detector positions.

In some aspects, implementations of the present disclosure include a non-transitory computer readable medium, wherein determining an optimized configuration of detectors includes iteratively selecting a plurality of detector placements.

In some aspects, implementations of the present disclosure include a non-transitory computer readable medium, wherein determining the optimized configuration of detectors includes applying a reinforcement learning (RL) algorithm.

In some aspects, implementations of the present disclosure include a non-transitory computer readable medium, wherein the RL includes Proper Orthogonal Decomposition (POD) based power reconstruction function paired with a reward function based on the power reconstruction error.

In some aspects, implementations of the present disclosure include a non-transitory computer readable medium, wherein the RL includes at least one of Proximal Policy Optimization, Deep Q-Network (DQN), Advantage Actor-Critic (A2C), and Monte Carlo Tree Search (MCTS).

In some aspects, implementations of the present disclosure include a non-transitory computer readable medium, wherein the second detector placement is determined by a trained agent configured to update the detector placement.

In some aspects, implementations of the present disclosure include a non-transitory computer readable medium, wherein the nuclear reactor model includes a model of a pressurized water reactor (PWR).

In some aspects, implementations of the present disclosure include a nuclear reactor system including: a reactor; and a plurality of detectors configured to monitor the reactor, the plurality of detectors being positioned at locations determined by: receiving a nuclear reactor model, wherein the nuclear reactor model includes a model of (i) at least one radiation source or flux and (ii) a plurality of candidate detector positions; constructing a Markov Decision Process (MDP) wherein the MDP includes a process for selecting detector placements and comparing simulated flux distribution and a reconstructed flux distribution for simulated detector placements; determining a reward function, wherein the reward function is configured to evaluate a power reconstruction error between the simulated flux distribution and the reconstructed flux distribution; selecting a first arrangement of detectors based on the MDP and performing a first evaluation of the first arrangement of detectors by the reward function; selecting a second arrangement of detectors based on the MDP and performing a second evaluation of the second arrangement of detectors by the reward function; determining an optimized configuration of detectors for the nuclear reactor model based on the first evaluation and the second evaluation, wherein the optimized configuration of detectors includes an assignment of detectors to at least one of the plurality of candidate detector positions.

In some aspects, implementations of the present disclosure include a nuclear reactor system, wherein determining an optimized configuration of detectors includes iteratively selecting a plurality of detector placements.

In some aspects, implementations of the present disclosure include a nuclear reactor system, wherein determining the optimized configuration of detectors includes applying a reinforcement learning (RL) algorithm.

In some aspects, implementations of the present disclosure include a nuclear reactor system, wherein the RL includes Proper Orthogonal Decomposition (POD) based power reconstruction function paired with a reward function based on the power reconstruction error.

In some aspects, implementations of the present disclosure include a nuclear reactor system, wherein the RL includes at least one of Proximal Policy Optimization, Deep Q-Network (DQN), Advantage Actor-Critic (A2C), and Monte Carlo Tree Search (MCTS).

In some aspects, implementations of the present disclosure include a nuclear reactor system, wherein the second detector placement is determined by a trained agent configured to update the detector placement.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF DRAWINGS

The accompanying drawings, which are incorporated in and constitute a part of this specification, illustrate embodiments and, together with the description, serve to explain the principles of the methods and systems.

FIG. 1 illustrates an example system for determining optimized placement of detectors in a nuclear reactor core, according to implementations of the present disclosure.

FIG. 2 illustrates an example method of determining the optimized placement of detectors in a nuclear reactor core, according to implementations of the present disclosure.

FIG. 3 illustrates a nuclear reactor core configured as an In-Core Detector Housings (ICDHs) in PWR core employed in a study including a radial layout of 58 potential ICDHs' location and axial placement of 6 SPNDs in each ICDH.

FIG. 4 illustrates an example Markov Decision Process (MDP) used in a study of an example implementation of the present disclosure.

FIG. 5 illustrates a framework for reinforcement learning based optimization of in-core detector configuration used in a study of an example implementation of the present disclosure.

FIG. 6 illustrates control rod and shutdown bank positions for a pressurized water reactor used in a study of an example implementation of the present disclosure.

FIG. 7 illustrates a relationship between reconstruction error and the number of Proper Orthogonal Decomposition basis, according to a study of an example implementation of the present disclosure.

FIG. 8 illustrates a relationship between Maximum Absolute Relative Error (MaxARe) in each epoch and epoch among five methods used in a study of an example implementation of the present disclosure.

FIG. 9 illustrates a relationship between Mean Absolute Relative Error (MeanARe) in each epoch and epoch among five methods used in a study of an example implementation of the present disclosure.

FIG. 10 illustrates a relationship between standard deviation in each epoch and epoch among five methods used in a study of an example implementation of the present disclosure.

FIG. 11 illustrates an example final optimal location of detectors among four models: PPO (proximal policy optimization), A2C (advantage actor-critic), MCTS (Monte-Carlo Tree Search) and GA (genetic algorithm) according to a study of an example implementation of the present disclosure.

### DETAILED DESCRIPTION

To facilitate an understanding of the principles and features of various embodiments of the present invention, they are explained hereinafter with reference to their implementation in illustrative embodiments.

The details of one or more embodiments of the invention are set forth in the accompanying drawings and the description below. Other features, objects, and advantages of the invention will be apparent from the description and drawings and from the claims.

Throughout the description and claims of this specification, the word “comprise” and other forms of the word, such as “comprising” and “comprises,” means including but not limited to, and is not intended to exclude, for example, other additives, components, integers, or steps.

To facilitate an understanding of the principles and features of various embodiments of the present invention, they are explained hereinafter with reference to their implementation in illustrative embodiments.

### Example System

The positioning of radiation detectors within a nuclear reactor is computationally challenging. The models of reactors and radiation flows within the reactor are complex, including three-dimensional geometries. Additionally, designers can choose many different locations for the radiation detectors and different numbers of radiation detectors. However, radiation detectors are also costly and complicated to add to the system, which can require a designer to optimize for fewer detectors with better detector placement. Moreover, designers can be subject to other constraints, for example a limitation that one detector be present at each horizontal compartment within the core, and the limitation that repositioning or testing detectors in a live nuclear reactor core can be extremely challenging. Often time, and as historically done, once detectors have been selected for a given core, a similar layout is applied to a future core. Because of the complexity and cost to reevaluate new core design, the core and detectors are not manually optimized for a given configuration.

For example, a designer may wish to find the arrangement of a certain number of detectors that causes the radiation measured at the detectors to best correlate with the actual radiation emitted by the reactor core. If there are more than 50 possible locations for each detector, and each location includes 6 vertical positions, there are more than 300 unique locations that each detector can be positioned in. And, if there are 6 detectors, then there can be more than 1000 potential designs that must be modeled to determine which arrangement of detectors best monitors the reactor. Further adding to the complexity, 6 detector configurations can be compared to 5 detector configurations and 7 detector configurations, and so on, such that many thousands of potential detector placements must be considered for optimizing the detector placement in any given reactor core. As described further with reference to the experimental results and additional examples, herein, implementations of the present disclosure can address these and other problems with conventional methods by automating the process of optimizing detector placement using reinforcement learning methods.

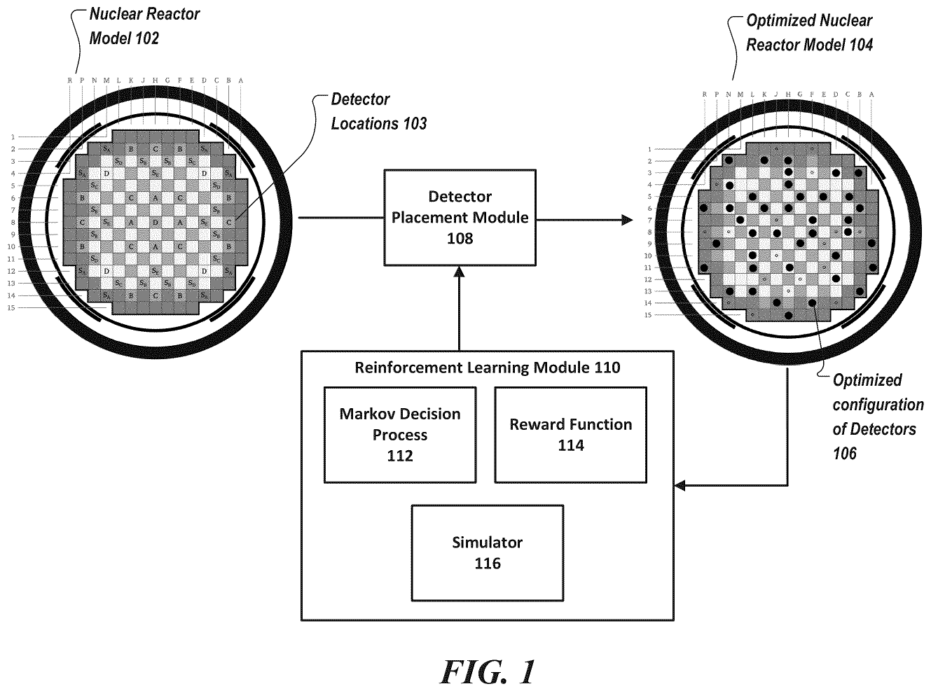

With reference to FIG. 1, an example block diagram is shown according to implementations of the present disclosure. A nuclear reactor model 102 can be used as an input. As shown in FIG. 1, the nuclear reactor model 102 can include a model of pressurized water reactor core, but it should be understood that the nuclear reactor model 102 can include additional parts of a nuclear reactor, and/or that the nuclear reactor model 102 can include different types of reactor.

A grid of potential detector locations 103 is included in the nuclear reactor model 102. Optionally, each of the potential detector locations 103 can include vertical positions within the nuclear reactor model 102.

A detector placement module 108 can be used to generate an optimized configuration of detectors 106 in an optimized nuclear reactor model 104. The detector placement module 108 can optionally include a trained agent configured to update the detector placement.

The system shown in FIG. 1 can use the detector placement module 108 to apply reinforcement learning to detector placement. The reinforcement learning module 110 can include an MDP 112 (Markov decision process), reward function 114, and simulator 116.

The simulator 116 can evaluate the optimized nuclear reactor model 104 by simulating a flux distribution and simulating the flux distribution detected by the optimized configuration of detectors 106. The simulator 116 can further evaluate a power reconstruction error that represents the actual power simulated by the simulator 116 compared to the power estimated by the optimized configuration of detectors 106 in the simulator. The MDP 112 can include a comparison between the simulated flux distribution of the simulator 116 and the reconstructed flux distribution of the optimized configuration of detectors 106 in the simulator 116.

The reward function 114 evaluates the relationship between the reconstructed flux distribution and simulated flux distribution to reward optimized configurations of detectors 106 that improve the reconstructed flux distribution and penalize optimized configurations of detectors 106 that do not improve the reconstructed flux distribution. The MDP 112 can output a new configuration of detectors based on the reward function 114 to the detector placement module 108.

The reinforcement learning module 110 can be configured to implement any reinforcement learning algorithm. Example reinforcement learning algorithms that can be used include Proximal Policy Optimization, Deep Q-Network (DQN), Advantage Actor-Critic (A2C), and Monte Carlo Tree Search (MCTS). The experimental results and additional examples, described below, include an implementation of the present disclosure using Proper Orthogonal Decomposition (POD) based a power reconstruction function paired with a reward function based on the power reconstruction error.

Optionally, the process illustrated in the system block diagram of FIG. 1 can be repeated any number of times (e.g., iteratively) to generate any number of optimized nuclear reactor models 104 and any number of optimized configurations of detectors 106. Accordingly, the system shown in FIG. 1 can be used to automatically select the best optimized configuration of detectors without requiring that all configurations of detectors be simulated, which can be prohibitively difficult computationally.

It should be understood that the detector placement module 108 and/or reinforcement learning module 110 can be implemented using the same or different computing devices (e.g., one or more servers in operable communication with each other). It should also be understood that the detector placement module 108 and/or reinforcement learning module 110 can be configured with specialized machine learning hardware to improve the performance of the detector placement module 108 and reinforcement learning module 110 when iteratively analyzing different configurations of detectors.

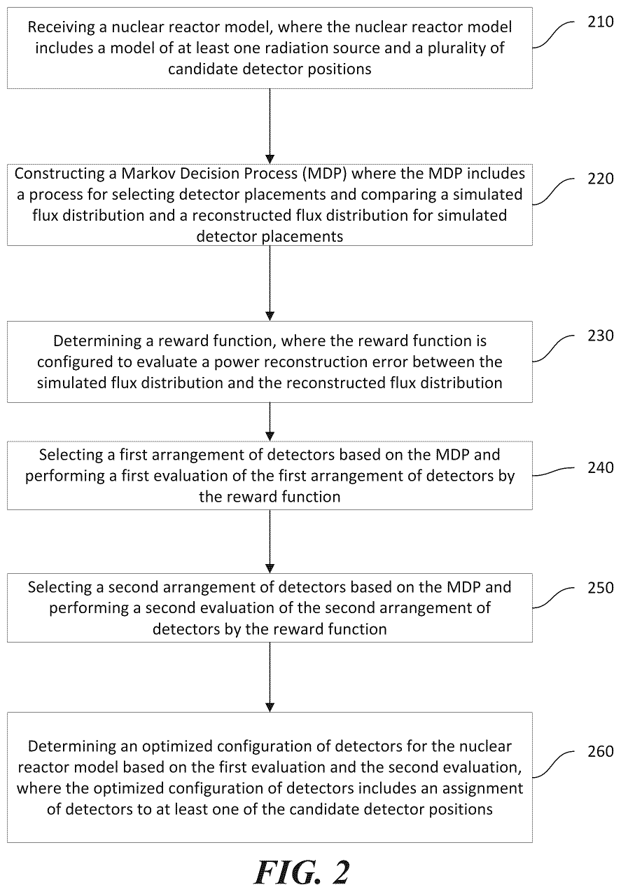

With reference to FIG. 2, an example method is shown according to implementations of the present disclosure.

At step 210, the method includes receiving a nuclear reactor model. The nuclear reactor model can include a model of a nuclear reactor core, including a model of the power flux through the core, including modeling the power flux in the core under different operating conditions. A non-limiting example of the nuclear reactor that can be modeled by the nuclear reactor model is a a pressurized water reactor (PWR).

A nuclear reactor core can be monitored by detectors configured to measure the power flux at different locations in the core. In some implementations, the nuclear reactor model includes a model of at least one radiation source and a number of candidate detector positions where the detectors can be placed.

At step 220, the method includes constructing a Markov Decision Process (MDP). The MDP can include a process for selecting detector placements and comparing a simulated flux distribution and a reconstructed flux distribution for simulated detector placements. The reconstructed flux distribution can be obtained by modeling the fluxes that would be measured by detectors located at detectors in a number of detector positions.

At step 230, the method can include determining a reward function. The reward function can be a function that evaluates a power reconstruction error between the simulated flux distribution and the reconstructed flux distribution to reward configurations of detectors that have reduced power reconstruction error.

At step 240, a first arrangement of detectors is selected. The first arrangement of detectors can include assigning detector positions to a number of detectors. A first evaluation of the first arrangement of detectors can be performed by the reward function.

At step 250, the method includes selecting a second arrangement of detectors. The second arrangement of detectors can also include an assignment of detector positions to a number of detectors. A trained agent can optionally be used to select the second detector placement.

At step 260, the method includes determining an optimized configuration of detectors for the nuclear reactor model based on the first evaluation and the second evaluation. As described in greater detail with reference to the experimental results and additional examples herein, the optimized configuration of detectors can include an assignment of detectors to the candidate detector positions. The optimized configuration of detectors can optionally be determined using a reinforcement learning algorithm. Non-limiting examples of reinforcement learning algorithms that can be used in implementations of the present disclosure include Proximal Policy Optimization, Deep Q-Network (DQN), Advantage Actor-Critic (A2C), and Monte Carlo Tree Search (MCTS). Alternatively or additionally, the reinforcement learning algorithm can include performing a Proper Orthogonal Decomposition (POD) based power reconstruction function paired with a reward function based on the power reconstruction error.

Optionally, any of the steps of FIG. 2 can be iteratively performed to evaluate any number of detector placements.

An example implementation was configured for the precise reconstruction of three-dimensional flux distribution within a reactor core by controlling the placement of detectors. The system includes an RL environment using algorithms such as PPO, DQN, A2C, and MCTS to award the RL agent rewards contingent on the reconstruction error, thereby driving the training process. Through ongoing interaction within this environment, the agent contributes towards establishing a detector layout that simultaneously minimizes the reconstruction error and complies with PDRS criteria.

In the example implementation, optimizing the location of in-core detectors is modeled as a Markov Decision Process and a Reinforcement Learning based framework is used to provide a solution for detector placement given a fixed number of detector and available detector positions. The RL-based framework can include an environment consisting of a Proper Orthogonal Decomposition (POD) based power reconstruction function paired with a novel reward function based on the power reconstruction error and a well-educated agent that updates the detector placement. Four RL algorithms including Proximal Policy Optimization, Deep QNetwork (DQN), Advantage Actor-Critic (A2C), and Monte Carlo Tree Search (MCTS) are investigated to optimize the detector placement and analyzed. Genetic Algorithm, a traditional optimization approach, is applied for comparison.

In-core detector arrangement optimization can be summarized as the task of choosing M positions out of N (N>M) positions to put detectors to minimize the power distribution reconstruction error for a given reconstruction model, which is defined in Equation 1 (below).

The crux of an MDP lies in discovering an optimal decision policy with an aim to achieve the highest expected reward. In the context of the optimal placement problem for in-core detectors, the objective is to discover an effective policy π, which facilitates the agent's action sequence (selecting the optimal location from potential positions in a particular order) leading to a superior power reconstruction outcome. RL algorithms used to derive the optimal policy π(s) broadly fall into two categories (Wiering et al., 2012): a) Value-based methods and Policy-based methods, also known as model-free methods, and b) Model-based methods. Value-based methods aim to select an action a for a specific state s with the goal of maximizing the action-value function Q^{π}(s, a). This function represents the expected reward under a policy π(s), s and a. On the other hand, policy-based methods employ a parametric function, π_{θ}(s), to directly approximate the agent's policy. By leveraging previous decisions or experiences made by the agent in the environment, these techniques fine-tune the parameters θ to optimize the reward defined as Eq. (2). Model-based methods form the second category. These methods can derive the optimal policy for the MDP problem, given that the transition probability P(sₜ₊₁|sₜ, αₜ) is known. A representative example of these algorithms is the Monte-Carlo Tree Search (MCTS), already utilized in the development of AlphaZero (Mnih et al., 2015). These RL algorithms, while varying in methodology and application, each offer unique insights into the optimization of policy decision-making in a given state-action space. Optimization of the configuration of in-core detectors is an NP-hard problem, and the present disclosure discloses solving this kind of problem as a MDP.

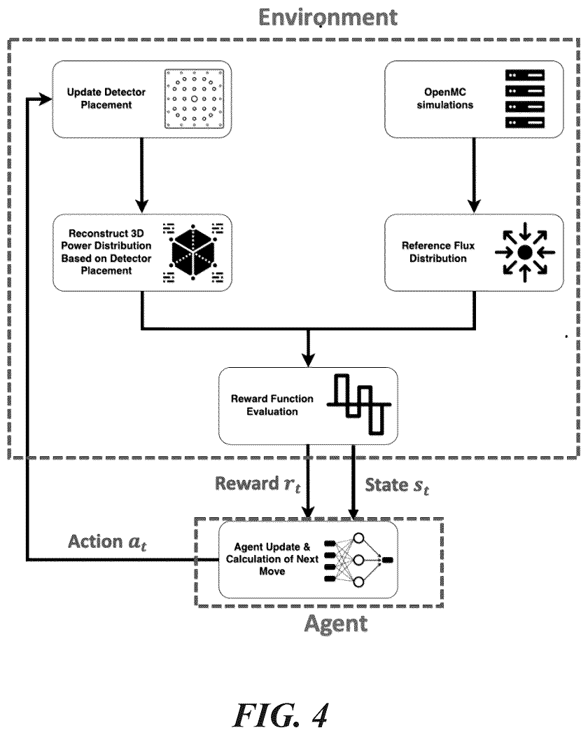

FIG. 4 shows the MDP for this problem, and primarily encapsulated within two fundamental phases: agent and environment. Agent represents the optimizer in our study, regulated by the RL algorithms that educates it to perform suitable actions. The environment corresponds to PDRS and the reactor core simulation (the power distribution cases of reactor core simulated by Monte Carlo code are the reference value). It receives the agent's action (input, signifying the selective location of in-core detectors), records the subsequent state and the reward, and relays them back to the agent.

The expected discounted rewards following policy π in state s can be defined by V^{π}(s), and similarly, the expectation for an action a following policy π in state s can be described by Q^{π}(s, a). These two value functions are closely related as demonstrated by the equation

$${V}^{π} ( s ) = {max}_{a} {Q}^{π} ( s , a ) ,$$

highlighting that the value of a state under a policy is the maximum expected return for any action in that state. Furthermore, the recursive nature of V^{π}(s) allows the value function to be broken down into the Bellman equation (Bellman, 1952), which outlines the calculation of V^{π}(s) using V^{π}(s′), where s′ represents possible subsequent states. The Bellman equation is defined in Equation 5 (below). Q^{π}(s, a) can also be decomposed into the form of Bellman equation, shown in Equation 6 (below).

In Equation (6) a′ is the possible following actions and π(a|s) is a policy probability function used to sample an action a under given a state s. According to the definition of V^{π}(s) and Q^{π}(s, a), two functions related to an optimal policy π*, optimal state value function V^{π*}(s) and the optimal action value function Q^{π*}(s, a), are defined in Equations 7 and 8 (below). Equations 7 and 8 show two approaches to find an optimal policy: pinpointing a sequence of actions that result in the maximization of V^{π}(s) on state s and leveraging the action-value function. Consequently, within the scope of value-based methodologies, the determination of the optimal policy necessitates the identification of the optimal value functions. It is worth pointing out that the explicit solution of the Bellman equation, that is, the discovery of the optimal value function, is feasible only when the transition function P(s′|s, a) is explicit. However, such an occurrence is rare in practical applications. Therefore, an optimal policy π* can be obtained by approximating the solution of Eq (5) or (6) for the current value-based methods.

Deep Q-networks (DQN) is one such value-based RL algorithms, that trains a neural network with parameters θ to approximate the values of Q^{π*}(s, a), i.e. Q_{θ}(s, a)≈Q^{π*}(s, a) (Mnih et al., 2015). An optimal approximation of Q^{π*}(s, a) with neural network can be obtained by minimizing the following loss function of Equation 9.

$$L ( {θ}_{i} ) = {𝔼}_{( s , a , r , {s}^{′} ) \sim D} [ {( {y}_{i} - {Q}_{{θ}_{i}} ( s , a ) )}^{2} ] \qquad ( 9 )$$

In Equation 9, yᵢ is TD (temporal difference) target, defined as

$${y}_{i} = r + γ {max}_{{a}^{′}} {Q}_{{θ}_{i - 1}} ( {s}^{′} , {a}^{′} ) and {y}_{i} - {Q}_{{θ}_{i}} ( s , a )$$

is referred to TD error, D serves as a replay memory buffer, responsible for storing trajectories of the form (s, a, r, s′). The training process using DQN has demonstrated enhanced robustness, leading to its successful application across a vast array of MDP problems. This algorithm can require the tuning of seven hyperparameters, namely εᵢₙᵢₜ, ε_{end}, τ, Bu, LS, Fₜᵣₐᵢₙ, B, Lr.

### Policy-Based Methods

Contrasting with value-based approaches, which can uncover Q*(s, a) and subsequently utilize a greedy strategy to deduce π*, policy-based methods strive to directly identify π*. This optimal policy is portrayed via a specific parametric function denoted as π_{θ}* and gradient ascent based on policy gradient theorem can be utilized to discover the optimal parameters θ (Sutton et al., 2000). This theorem presents the gradients in the following format of Equation 10 (below).

The return estimate Â(sₜ, aₜ) is defined as Â(sₜ, aₜ)=Σ_{t=t′}^{T}t^{t′-t}r(s^{t}′, a^{t}′)−b(sₜ), where T represents the agent's time horizon and b(s) corresponds to the baseline function. The parameters θ are subsequently optimized by the gradient descent algorithm utilizing the policy's gradient.

As another example, Proximal Policy Optimization (PPO) is grounded in the policy gradient paradigm, but it introduces an additional level of sophistication which is operated by implementing policy updates within controlled constraints in the policy space (Schulman et al., 2017).

In the loss function Â(sₜ, aₜ) can be obtained by Eq. (11), CLIP in the equation denotes the clipping range. The initial term found within the minimum function represents a revised policy gradient (PG) objective, incorporating a trust-region feature (Schulman et al., 2015). The second term further refines the objective by introducing a clipping mechanism to the probability ratio. This clipping strategy helps to constrain the reward rₜ, preventing it from surpassing the predefined boundary range of [1−CLIP, 1+CLIP]. In contrast to hyper-parameter sets of DQN, PPO utilizes a parameter λ acting as a balancing factor in the bias-variance trade-off for the generalized advantage estimator, specifically in the estimate of the advantage function.

### Monte-Carlo Tree Search

Monte-Carlo Tree Search (MCTS) represents one of heuristic search methodologies that is applicable for decision processes in both deterministic and stochastic environments (Mnih et al., 2015; Browne et al., 2012). It fundamentally combines two distinct elements: tree search techniques that systematically explore possible decision paths, and Monte Carlo simulation, which infers the value of unknown quantities leveraging statistical principles. The algorithm constructs a search tree incrementally and strategically decides the most promising node based on the information available at the current exploration stage.

In Equation 13, N(s) is the number of time that particular node is visited, while N(s, a) represents the frequency of a move being executed in the state s, K can balance between exploration and exploitation. The expansion stage extends the search tree by one node. In the simulation phase, a Monte Carlo simulation is carried out from the newly incorporated node to the conclusion of the problem scenario. Finally, the Backpropagation stage propagates the simulation results from the new node back to the root node.

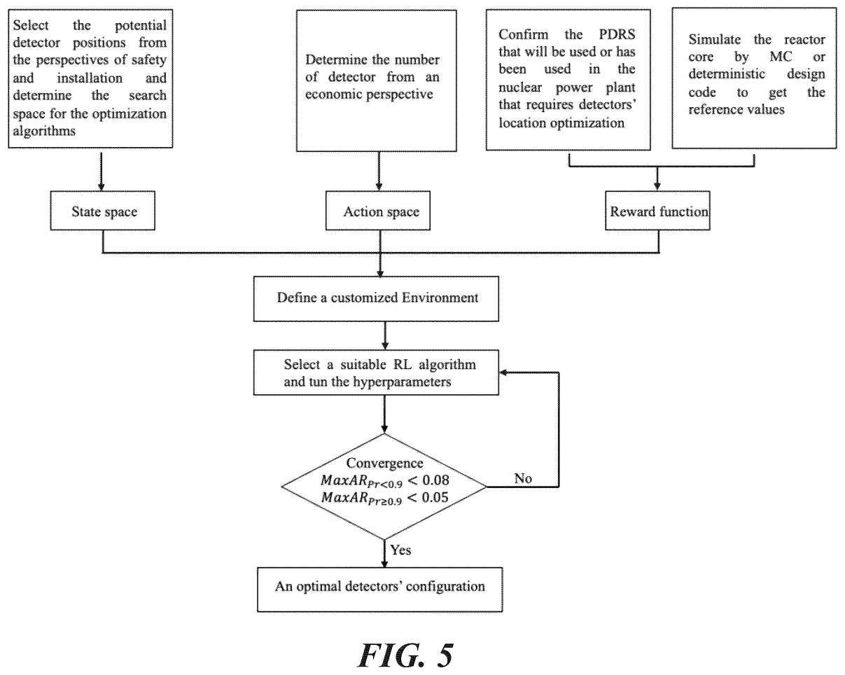

RL algorithms including PPO, DQN, MCTS and A2C can be employed to optimize the configuration of in-core detectors. The goal can be to achieve the most favorable arrangement that results in the highest power reconstruction accuracy. FIG. 5 graphically represents the RL based optimization framework for in-core detector configuration. The process begins by defining the state space, which is the search area, from an engineering and safety perspective. Subsequently, the number of detectors is determined based on economic considerations. A crucial part of this framework is the definition of the reward function, which informs three key tasks integral to resolving the optimization problem: a) Dataset Generation: The primary aim is to develop an online power reconstruction system predicated on the generated dataset. This system also provides reference data for assessing the environment, enabling the allocation of rewards at each action step. b) Power Reconstruction System Development: The Proper Orthogonal Decomposition (POD) algorithm is employed to establish a power reconstruction system, thereby enhancing data processing capabilities. c) Execution of Detector Position Optimization: This phase entails the application of RL algorithms to the predefined customized environment, which is built on the outcomes of the initial two stages. The determined reward/fitness function plays a crucial role as it steers the optimization process towards solutions that not only maximize system performance but also comply with PDRS criteria.

### Experimental Results and Additional Examples

A study was conducted to develop and evaluate an example implementation of the present disclosure configured for detector placement in a pressurized water reactor.

The precise reconstruction of three-dimensional flux distribution within a reactor core is imperative for effective monitoring and control, necessitating the optimization of in-core detector configurations. This task can be likened to selecting M positions from a total of N (where N>M) to place the detectors, a configuration which should aim to minimize the variance of a given reconstruction model. The substantial size of the search space, including up to 58 potential permutations, even after considering factors like reactor physics and mechanical failures, renders a brute-force search strategy for the optimal combination impracticable. In this research, the study framed the optimization problem as a MDP and formulated a RL based optimization framework, which not only improves efficiency but also enhances the capacity for optimal value discovery. Furthermore, the versatility of this framework allows its application to other types of reactors facing similar challenges.

The study began with the development of a pragmatic core power reconstruction system, utilizing the POD method. This system was subsequently integrated into a RL environment. This environment, which utilizes algorithms such as PPO, DQN, A2C, and MCTS, awards the RL agent rewards contingent on the reconstruction error, thereby driving the training process. Through ongoing interaction within this environment, the agent contributes towards establishing a detector layout that simultaneously minimizes the reconstruction error and complies with PDRS criteria. To benchmark the results achieved through RL, the study implemented the GA method, with the inverse of the reconstruction error function serving as the fitness value. However, in comparison to RL algorithms like A2C and MCTS, the GA method exhibited a relatively limited capacity for exploration, generating fewer feasible solutions within an equivalent time step. Intriguingly, PPO demonstrated a superior performance, producing feasible solutions at a rate comparable to GA and showing a greater propensity towards a global solution, as indicated by the change in standard variance. Benefitting from the inherent attributes of RL, the present disclosure includes reward functions, and defines action and state spaces that meet specified engineering requirements and objectives in a logical manner. Currently, the search space is constrained to a manageable 58 potential detector positions, deemed appropriate from an engineering viewpoint. The present disclosure contemplates that the methods described herein can be used to extend the search space and delve into optimization possibilities from as many as 193 potential detector positions spread throughout the entirety of the reactor core, whilst maintaining strict adherence to engineering constraints.

TABLE
Definitions. As used in the study of the example embodiment,
the following acronyms and abbreviations are defined.

| Abbreviation | Text | Abbreviation | Text |
|---|---|---|---|
| DQN | Deep Q Learning | | |
| MCTS | Monte-Carlo Tree Search | Fₜᵣₐᵢₙ | Frequency of model |
| | | | training |
| PPO | Proximal Policy | TS | Time Step |
| | Optimization | | |
| A2C | Advantage Actor Critic | V^{π}(s) | State value function |
| GA | Genetic algorithms | Q^{π}(s, a) | Action-value function |
| POD | Proper Orthogonal | PDRS | Power Distribution |
| | Decomposition | | Reconstruction System |
| γ | Discount factor | MaxG | GA maximum generations |
| s₀ | Initial state | ent_{coef} | Entropy coefficient |
| MDP | Markov decision process | vf_{coef} | Value function loss |
| | | | coefficient |
| π(s) | Decision policy | MGnorm | Maximum value for |
| | | | gradient clipping |
| CLIP | Clipping parameter for | Time limit | Constraint of time-bound |
| | PPO | | MCTS |
| λ | PPO bias-variance trade- | κ | MCTS Exploration ratio |
| | off | | |
| Mu | GA mutation ratio | CS | Crossover ratio |
| ρ | Ratio of elitists in | ε | Trade-off between |
| | upcoming generations | | exploitation and |
| | for GA | | exploration for DQN |

Monitoring three-dimensional (3D) flux distribution in a nuclear reactor core can be used to improve safety and economics, which can require strategically-placed in-core detectors. However, the deployment of these sensors is often constrained by physical, industrial, and economic limitations. The study treated optimizing the location of in-core detectors as a Markov Decision Process and developed a Reinforcement Learning based framework to provide a solution for detector placement given a fixed number of detector and available detector positions. The RL-based framework contains an environment consisting of a Proper Orthogonal Decomposition (POD) based power reconstruction function paired with a novel reward function based on the power reconstruction error and a well-educated agent that updates the detector placement. Four RL algorithms including Proximal Policy Optimization, Deep QNetwork (DQN), Advantage Actor-Critic (A2C), and Monte Carlo Tree Search (MCTS) are investigated to optimize the detector placement and analyzed. Genetic Algorithm, a traditional optimization approach, is applied for comparison. The study shows that RL outperforms GA in terms of the quality of optimal solutions, demonstrating an inclination towards locating a global solution. Moreover, the flexible nature of RL enables the integration of developed novel reward functions from a specific reactor core into other reactors, considering the particular engineering requirements within the RL-based framework, thereby enhancing the optimization of in-core detector configurations.

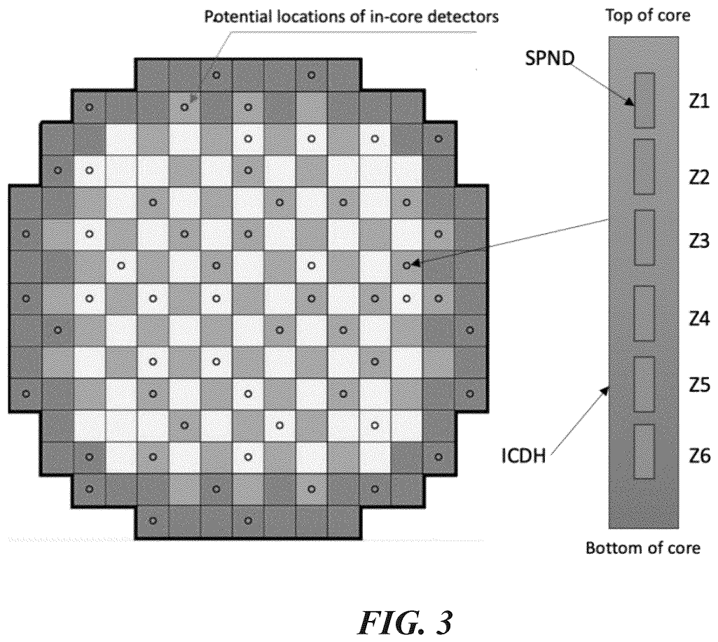

For the safe operation of a nuclear reactor, continuous monitoring of the online in-core power distribution can be required. Generally, a reliable power distribution monitoring system also called power distribution reconstruction system (PDRS) providing significant details needs a great number of reasonably-positioned in-core detectors. In addition, the power distribution is more important in advanced reactors, as some of them are designed to have autonomous control as well as load following features. Advanced control techniques and approaches typically rely more heavily on accurate sensor measurements and information on the plant state. Ideally, high-level situational awareness can be achieved by a large number of sensors. However, even within advanced reactor designs there are still physical, industrial, and economical constrains limiting the number of sensors and their location of installation. For example, microreactors may have limited space to install sensors, and may also be limited by per-unit affordability or maintenance constraints. Therefore, optimizing the location of in-core detectors under a given number of detectors, with a trade-off made between safety, economy and measurement accuracy, can be computationally challenging. FIG. 3 shows the potential radial and axial locations of in-core detectors used in this work. FIG. 3 represents different types of fuel assembly and the detectors are inserted into assembly. The Self-Powered Neutron Detector (SPND), as indicated in FIG. 3, serves as a prevalently utilized in-core, immobile neutron sensing apparatus. Incorporated within the core of the AP1000 reactor, these SPNDs employ Vanadium-51 (V51) as their neutron-responsive material (Huang et al., 2012). They are arrayed within multiple In-Core Detector Housing (ICDH) units and each ICDH modules possesses the capability to accommodate a maximum of ten discrete SPNDs (Yellapu et al., 2017). These detectors are compartmentalized within individual thimbles, thereby facilitating their vertical positioning at unique locations within the nuclear reactor core.

In-core detector arrangement optimization aims to provide as much information of in-core power distribution as possible under given number of the detectors in available positions. It can be summarized as the task of choosing M positions out of N(N>M) positions to put detectors to minimize the power distribution reconstruction error for a given reconstruction model, which is defined in Equation 1.

$$\{ \begin{matrix}{MIN}_{σ} ( Y ) \\ {\sum }_{i = 1}^{N} {Y}_{i} = M \\ {Y}_{i} = \{ \begin{matrix}1 , & detector in i - th assembly \\ 0 , & no detector in i - th assembly\end{matrix} , i = 1 , 2 , 3 … N\end{matrix} \qquad ( 1 )$$

In Equation 1, Y=(Y₁, Y₂, Y₃, . . . , Y_{N}) is the layout of detector in reactor core, σ(Y) is the variance of the PDRS. This optimization problem has a very high computational cost if using brute force search. For example, putting 30 detectors into the reactor core with 17×17 assemblies have approximately 10⁴¹(Πₖ₌₃₀²⁸⁹ k/Πₖ₌₁³⁰ k) arrangements.

To find an optimal detector configuration, two primary methodologies are currently in use which are called direct and indirect methods. Direct methods strive to reduce the state reconstruction error such as node power values and power peaking factors by modifying the number or location of sensors within the reactor core (Mishra et al., 2012). A critical limitation of this approach, however, is that using the approximate power distribution information reconstruction function instead of PDRS as evaluation function could cause an inaccurate detectors' configuration. Indirect methods, on the other hand, focus on identifying the best configuration of in-core detector by minimization or maximization of evaluations for potential location of detector like variance, entropy, and Pearson correlation instead of PDRS (Oh et al., 1994; Bahuguna et al., 2023; Anupreethi et al., 2020; Argaud et al., 2018, Terman et al., 2018; Mishra et al., 2012). For instance, the variance-based methods align with our focus on locations that exhibit large shifts in state parameters, as indicated by high variance. Despite this, these methods are not without their drawbacks. They are reliant on the evaluation function and, for example, the minimization of mutual information between sensor pairs or the total correlation across all sensors does not inherently guarantee the minimization of all shared information among in-core detectors (Terman et al., 2018; Mishra et al., 2012). In conclusion, while each of these methods offers certain advantages, the quality of optimal solutions from these methods shares a common reliance on the evaluation function. The complexity and high computational cost of a real power/flux reconstruction system impede its direct use as an “evaluation function.” Consequently, a different approach is warranted to overcome these limitations. In this work, the process of finding an optimal detectors' locations is considered as a Markov Decision Process (MDP) and a Reinforcement Learning (RL) based framework is developed for this problem while solving the limitations posed by current methods discussed above. RL algorithms are adaptable and can learn from feedback, making them suitable for complex optimization missions with changing conditions, and it has been used in the field of nuclear engineering recently (Sutton et al., 2018; Radaideh et al., 2022; Gu et al., 2023). In the developed RL framework, the awards are based on the evaluation function in PDRS (environment), which inspires agent to explore the search space effectively and efficiently to find the best solution. Besides, Genetic Algorithm (GA), a traditional optimization algorithm and as the baseline for this proposed framework, is used to provide the optimal detector placement solutions for the fixed number of detectors.

### Methodology

Reinforcement Learning. Reinforcement learning is a branch of machine learning that can be used to solve the problem conceptualized as a Markov decision process (MDP) by concerning with which action the agents should take in an environment to obtain a maximum cumulative reward (H. V. Hasselt, 2010). MDP is a stochastic process model primarily utilized in discrete-time control mechanisms which is served as a mathematical foundation for characterizing decision-making scenarios that involve a blend of random events and actions influenced by a decision-maker. In the paradigm of an MDP, an agent is in continuous interaction with the surrounding environment, making a chain of decisions aimed at maximizing a specified objective, such as enhancing precision or performance. Concisely, an MDP can be presented as a tuple M= [symbol] S, A, R(s, a), P(sₜ₊₁|sₜ, aₜ), γ, s₀ [symbol] , as described in the following table.

| Term | Definition |
|---|---|
| S - State space | S encapsulates the set of potential states, denoted as sₜ ∈ S, which |
| | the system could assume. In the context of this study, sₜ symbolizes |
| | the arrangement of in-core detectors. |
| A - Action space | A outlines the array of actions, represented as aₜ ∈ A, that an agent |
| | can execute. The action aₜ is defined as a chosen detector location |
| | from among possible locations. |
| R(s,a) - Reward | Reward function: the reward function is a mapping procedure that |
| function | assigns real numbers to combinations of states and actions. Rewards |
| | exemplify the impact of a selected action in a particular state on the |
| | solution quality of the problem. Reward serves as an agent's |
| | performance indicator, in this case referring to the inverse of the |
| | power reconstruction error, thereby implying that the maximum |
| | reward corresponds to the minimum reconstruction error. |
| P(sₜ₊₁ \| sₜ, aₜ) | State transition probabilities function: this function manages the |
| | transition dynamics that steer the system from one state to another |
| | according to an action. |
| γ - Discount factor | Discount factor: a scalar value ranging from 0 to 1, the discount |
| | factor incentivizes the agent to prioritize immediate rewards. A |
| | higher γ value increases the relative importance of future rewards in |
| | determining present action, while a lower γ value suggests a |
| | shortsighted agent with a focus on instantaneous rewards. |
| s₀ - Initial state | s₀ represents the potential detector locations configuration with none |
| | of detectors to put in the reactor core, implying no action can be |
| | initially taken. |

The crux of an MDP lies in discovering an optimal decision policy with an aim to achieve the highest expected reward. The mathematical expression is given as:

$${arg max}_{π} \{ 𝔼 [ {\sum }_{t = 0}^{T - 1} {γ}^{t} R ( {s}_{t} , {a}_{t} ) ] \} \qquad ( 2 )$$

In Equation 2, π(s) is a decision policy, aₜ=π(sₜ), and the next state sₜ₊₁ can be obtained by sampling according to the P(sₜ₊₁|sₜ, aₜ). In the context of the optimal placement problem for in-core detectors, the objective is to discover an effective policy π, which facilitates the agent's action sequence (selecting the optimal location from potential positions in a particular order) leading to a superior power reconstruction outcome. RL algorithms used to derive the optimal policy π(s) broadly fall into two categories (Wiering et al., 2012): a) Value-based methods and Policy-based methods, also known as model-free methods, and b) Model-based methods. Value-based methods aim to select an action a for a specific state s with the goal of maximizing the action-value function Q^{π}(s, a). This function represents the expected reward under a policy π(s), s and a. On the other hand, policy-based methods employ a parametric function, π_{θ}(s), to directly approximate the agent's policy. By leveraging previous decisions or experiences made by the agent in the environment, these techniques fine-tune the parameters θ to optimize the reward defined as Eq. (2). Model-based methods form the second category. These methods can derive the optimal policy for the MDP problem, given that the transition probability P(sₜ₊₁|sₜ, aₜ) is known. A representative example of these algorithms is the Monte-Carlo Tree Search (MCTS), already utilized in the development of AlphaZero (Mnih et al., 2015). These RL algorithms, while varying in methodology and application, each offer unique insights into the optimization of policy decision-making in a given state-action space. Optimization of the configuration of in-core detectors is an NP-hard problem, and the present disclosure considers the process of solving this kind of problem as a MDP in this work.

FIG. 4 shows the MDP for this problem, and primarily encapsulated within two fundamental phases: agent and environment. Agent represents the optimizer in our study, regulated by the RL algorithms that educates it to perform suitable actions. The environment corresponds to PDRS and the reactor core simulation (the power distribution cases of reactor core simulated by Monte Carlo code are the reference value). It receives the agent's action (input, signifying the selective location of in-core detectors), records the subsequent state and the reward, and relays them back to the agent. The chain of this operations is facilitated by the step function within the customized environment based on OpenAI Gym (Radaideh et al., 2022).

To gauge the effectiveness of RL algorithms vis-a-vis the GA, a widely-used optimization technique, it is essential to clarify certain terminologies integral to the training process:
Time Step (TS): A time step signifies a single interaction between the agent and the environment, equating to one call of the step function. For the majority of our computational work, the study employed a workstation equipped with a 96-processor, 128 GB RAM, and an AMD EPYC 7763 64-Core Processor.
Episode: An episode denotes a series of steps undertaken by the agent from the commencement to the conclusion of a game or task. In this context, an episode initiates with the initial arrangement of the detectors' locations, as illustrated in FIG. 1(a), and concludes when a predetermined number of detectors have been placed into the reactor core. An adequate number of such episodes are typically executed until the agent acquires sufficient knowledge to undertake the suitable action based on the provided state, thereby optimizing the ensuing reward.
Epoch: The size of an epoch is meticulously calibrated to strike a balance between computational cost and accuracy. This essentially means that the data is processed in chunks or “epochs” to manage resource use while ensuring sufficient accuracy in the learning process.

### Value-Based Methods

Before introducing the RL methods, it is imperative to show the value function. A value function can measure how good each state or (state, action) tuple is by predicting the expectation of the discounted rewards, which includes the state value function V^{π}(s) and action-value function Q^{π}(s, a), which are defined in Equations 3 and 4.

$${V}^{π} ( s ) = 𝔼 [ {R}_{t} \vert {s}_{t} = s ] \qquad ( 3 )$$

$${Q}^{π} ( s , a ) = 𝔼 [ {R}_{t} \vert {s}_{t} = s , {a}_{t} = a ] \qquad ( 4 )$$

The expected discounted rewards following policy π in state s can be defined by V^{π}(s), and similarly, the expectation for an action a following policy π in state s can be described by Q^{π}(s, a). These two value functions are closely related as demonstrated by the equation

$${V}^{π} ( s ) = {max}_{a} {Q}^{π} ( s , a ) ,$$

highlighting that the value of a state under a policy is the maximum expected return for any action in that state. Furthermore, the recursive nature of V^{π}(s) allows the value function to be broken down into the Bellman equation (Bellman, 1952), which outlines the calculation of V^{π}(s) using V^{π}(s′), where s′ represents possible subsequent states. The Bellman equation is defined in Equation 5.

$${V}^{π} ( s ) = {\sum }_{a} π ( a \vert s ) {\sum }_{{s}^{′}} P ( {s}^{′} \vert s , a ) [ r + γ {V}^{π} ( {s}^{′} ) ] \qquad ( 5 )$$

Q^{π}(s, a) can also be decomposed into the form of Bellman equation, shown in Equation 6.

$${Q}^{π} ( s , a ) = {\sum }_{{s}^{′}} P ( {s}^{′} \vert s , a ) [ r + γ {\sum }_{{a}^{′}} π ( {a}^{′} \vert {s}^{′} ) {Q}^{π} ( {s}^{′} , {a}^{′} ) ] \qquad ( 6 )$$

In Equation (6) a′ is the possible following actions and π(a|s) is a policy probability function used to sample an action a under given a state s. According to the definition of V^{π}(s) and Q^{π}(s, a), two functions related to an optimal policy π*, optimal state value function V^{π*}(s) and the optimal action value function Q^{π*}(s, a), are defined in Equations 7 and 8.

$${V}^{π} * ( s ) = {max}_{π} {V}^{π} ( s ) = {max}_{a} {Q}^{π} * ( s , a ) \qquad ( 7 )$$

$${Q}^{π} * ( s , a ) = {max}_{π} {Q}^{π} ( s , a ) \qquad ( 8 )$$

Equations 7 and 8 show two approaches to find an optimal policy: pinpointing a sequence of actions that result in the maximization of V^{π*}(s) on state s and leveraging the action-value function. Consequently, within the scope of value-based methodologies, the determination of the optimal policy necessitates the identification of the optimal value functions. It is worth pointing out that the explicit solution of the Bellman equation, that is, the discovery of the optimal value function, is feasible only when the transition function P(s′|s, a) is explicit. However, such an occurrence is rare in practical applications. Therefore, an optimal policy π* can be obtained by approximating the solution of Eq (5) or (6) for the current value-based methods.

Deep Q-networks (DQN) is one such value-based RL algorithms, that trains a neural network with parameters θ to approximate the values of Q^{π*}(s, a), i.e. Q_{θ}(s, a)≈Q^{π*}(s, a) (Mnih et al., 2015). An optimal approximation of Q^{π*}(s, a) with neural network can be obtained by minimizing the following loss function of Equation 9.

$$L ( {θ}_{i} ) = {𝔼}_{( s , a , r , {s}^{′} ) ∼ D} [ {( {y}_{i} - {Q}_{{θ}_{i}} ( s , a ) )}^{2} ] \qquad ( 9 )$$

In Equation 9, yᵢ is TD (temporal difference) target, defined as

$${y}_{i} = r + γ {max}_{{a}^{′}} {Q}_{{θ}_{i - 1}} ( {s}^{′} , {a}^{′} ) and {y}_{i} - {Q}_{{θ}_{i}} ( s , a )$$

is referred to TD error, D serves as a replay memory buffer, responsible for storing trajectories of the form (s, a, r, s′). The training process using DQN has demonstrated enhanced robustness, leading to its successful application across a vast array of MDP problems. This algorithm can require the tuning of seven hyperparameters, namely εᵢₙᵢₜ, ε_{end}, T, Bu, Ls, Fₜᵣₐᵢₙ, B, Lr.

The parameters εᵢₙᵢₜ and ε_{end} play a fundamental role in arbitrating the trade-off between exploitation and exploration. Initially, the agent selects a random action with a probability denoted by εᵢₙᵢₜ, an exploration-centric strategy. This probability is progressively annealed to ε_{end}, providing a controlled transition from exploration to exploitation. Higher values invigorate exploration, potentially enhancing policy learning; however, this might be accompanied by an immediate reward diminution. The parameter Bu is responsible for dictating the dimensions of the replay buffer, a pivotal component where the agent archives previous experiences to facilitate off-policy learning. An expansive buffer encapsulates more experiences and may potentially augment learning performance, but it might incur higher computational demands. The Ls parameter specifies the number of steps the agent must undertake before initiating learning from the replay buffer, thereby ensuring a wealth of experiences are accumulated for effective learning. Fₜᵣₐᵢₙ designates the frequency with which the agent refers to the replay buffer for learning purposes. Although heightened frequency could lead to accelerated adaptation, it might also engender overfitting towards recent experiences and could inject instability into the learning process. Batch size, B, denotes the quantity of experiences sampled from the replay buffer for each learning update. Larger batch sizes potentially stabilize the learning process but could increase the computational expenditure. The parameter τ represents the soft update coefficient for the target network, controlling the rate at which the target network approximates the primary network at each step. A conservative tau ensures the target network evolves gradually, aiding overall stability. The learning rate Lr is associated with the optimizer. A high learning rate implies the agent modifies its policy drastically during each update, a trait that can catalyze rapid learning but might cause instability.

### Policy-Based Methods

Contrasting with value-based approaches, which can uncover Q*(s, a) and subsequently utilize a greedy strategy to deduce π*, policy-based methods strive to directly identify π*. This optimal policy is portrayed via a specific parametric function denoted as no and gradient ascent based on policy gradient theorem can be utilized to discover the optimal parameters θ (Sutton et al., 2000). This theorem presents the gradients in the following format of Equation 10.

$${∇}_{θ} J ( {π}_{θ} ) = {𝔼}_{{π}_{θ}} [ {\sum }_{t = 0}^{T} {∇}_{θ} log {π}_{θ} ( {a}_{t} \vert {s}_{t} ) \hat{A} ( {s}_{t} , {a}_{t} ) ] \qquad ( 10 )$$

The return estimate Â(sₜ, aₜ) is defined as Â(sₜ, aₜ)=Σ_{t=t′}^{T}t^{t′-t}r(s^{t}′, a^{t}′)−b(sₜ), where T represents the agent's time horizon and b(s) corresponds to the baseline function. The parameters θ are subsequently optimized by the gradient descent algorithm utilizing the policy's gradient.

The function b(s) primarily serves to decrease the variance of Â(sₜ, aₜ). Given that the policy π_{θ}(a|s) is executed using the current parameters, the baseline function helps to improve the initial poor performance during the commencement of training by reducing this variance. If the study eliminates the baseline b(sₜ) from the return estimate, the REINFORCE algorithm is obtained (Williams and Ronald J, 1992). Alternatively, the baseline value b(sₜ) can be computed either by calculating the mean reward across sampling trajectories or employing V_{ϕ}(sₜ) called the parametric value function estimator. The Actor-Critic family of algorithms such as Advantage Actor Critic (A2C) and Asynchronous Advantage Actor Critic (A3C) extends the REINFORCE algorithm, employing bootstrapping to update state-value estimates using subsequent state values (Mnih et al., 2016). One common technique involves utilizing a parametric value function to estimate the return for each time step, as shown in Equation 11:

$$\hat{A} ( {s}_{t} , {a}_{t} ) = r ( {s}_{t} , {a}_{t} ) + {V}_{ϕ} ( {s}_{t}^{′} ) - {V}_{ϕ} ( {s}_{t} ) \qquad ( 11 )$$

This method introduces bias into gradient estimations; however, it frequently further reduces variance. The Actor-Critic methods, versatile in their application to continual learning and online learning, rely not on Monte Carlo rollouts, but rather bypass the need to unroll the trajectory to the final state. A2C is one of the methods used in this paper and there are some different parameters in A2C algorithm comparing with DQN. “ent coef” is the entropy coefficient, determining the contribution of the entropy to the overall loss function. Encouraging exploration, the entropy bonus penalizes the policy when it's deterministic and rewards it when it's more random. Tuning this coefficient can help balance exploration and exploitation. vƒ_{coef} is the coefficient for the value function loss in the combined loss function. Tuning this value can help control the trade-off between policy and value estimation. The parameter MGnorm is the maximum value for gradient clipping. Clipping the gradients can prevent large updates and help stabilize the learning process. This can be particularly important in settings where there's a risk of experiencing very high gradients that can disrupt learning.

While A2C has been influential, the field has continued to innovate and expand. A notable development is the introduction of Proximal Policy Optimization (PPO). Like A2C, PPO is grounded in the policy gradient paradigm, but it introduces an additional level of sophistication which is operated by implementing policy updates within controlled constraints in the policy space (Schulman et al., 2017). This algorithm has gained popularity in RL and is commonly used to train agents to accomplish tasks within a specific environment. PPO is a variant of the policy gradient algorithm, and its objective is to enhance the agent's policy by maximizing the expected return derived from actions. The loss function for the clipped PPO is defined as follows:

$${L}^{CLIP} ( θ ) = {E}_{t} \{ min ( \frac{{π}_{θ} ( {a}_{t} \vert {s}_{t} )}{{π}_{{θ}_{old}} ( {a}_{t} \vert {s}_{t} )} \hat{A} ( {s}_{t} , {a}_{t} ) .$$

In the loss function Â(sₜ, aₜ) can be obtained by Eq. (11), CLIP in the equation denotes the clipping range. The initial term found within the minimum function represents a revised policy gradient (PG) objective, incorporating a trust-region feature (Schulman et al., 2015). The second term further refines the objective by introducing a clipping mechanism to the probability ratio. This clipping strategy helps to constrain the reward rₜ, preventing it from surpassing the predefined boundary range of [1−CLIP, 1+CLIP]. In contrast to hyper-parameter sets of DQN, PPO utilizes a parameter/acting as a balancing factor in the bias-variance trade-off for the generalized advantage estimator, specifically in the estimate of the advantage function.

### Monte-Carlo Tree Search

Monte-Carlo Tree Search (MCTS) represents one of heuristic search methodologies that is applicable for decision processes in both deterministic and stochastic environments (Mnih et al., 2015; Browne et al., 2012). It fundamentally combines two distinct elements: tree search techniques that systematically explore possible decision paths, and Monte Carlo simulation, which infers the value of unknown quantities leveraging statistical principles. The algorithm constructs a search tree incrementally and strategically decides the most promising node based on the information available at the current exploration stage. The present disclosure includes a time-bound MCTS, where the search operation is constrained by a specified time limit which is set to a particular value that balances between computational resources and the quality of the solution. This also allows control of the duration of the search, ensuring that the algorithm returns a result within a reasonable timeframe, even if it hasn't fully explored all possible paths in the search tree. The MCTS algorithm (Browne et al., 2012), encompassing four main stages: selection, expansion, Monte-Carlo simulation, and backpropagation, is shown as Algorithm 1. The selection stage involves traversing the search tree from the root, also known as the initial state, so, to a leaf node also called s by selecting optimal child nodes. A classical selection method is to use Upper Confidence Bounds as illustrated in Equation 13.

$$a *= {argmax}_{a ∈ A} \{ {Q}^{π} ( s , a ) + κ \sqrt{\frac{ln N ( s )}{N ( s , a )}} \} \qquad ( 13 )$$

In Equation 13, N(s) is the number of time that particular node is visited, while N(s, a) represents the frequency of a move being executed in the state s, κ can balance between exploration and exploitation. The expansion stage extends the search tree by one node. In the simulation phase, a Monte Carlo simulation is carried out from the newly incorporated node to the conclusion of the problem scenario. Finally, the Backpropagation stage propagates the simulation results from the new node back to the root node.

Algorithm 1: Monte-Carlo Tree Search

| | |
|---|---|
| 1. | Initialize the exploration tree with s₀ as root. |
| 2. | While the number of detectors placed is less than the fixed number: |
| 2(a). | Selection: (1) Set current node as the root. (2) while the node is not a leaf node: |
| | a. Designate the current node as the child node as defined by Eq (12). |
| 2(b). | Expansion (1) If current node is not terminal: a. Expand current node by adding all |
| | possible action nodes as its children. b. Set current node as any child of the expanded |
| | node. |
| 2(c). | Simulation (1) Perform a rollout from current node using a random policy and obtain |
| | the reward. |
| 2(d). | Backpropagation (1) while current node is not None: a. Update the visit count and |
| | total reward of current node. b. Set current node as its parent. |
| 3. | Set an optimal detector position as positions of the detectors in the state with the |
| | highest average reward. |
| 4. | Return an optimal detector position. |

### Genetic Algorithm

Genetic algorithms (GAs) encompass a suite of stochastic search strategies targeted at solving optimization challenges, including continuous (differentiable and non-differentiable) and discrete problems (Sivanandam et al., 2008). These algorithms are adept at handling constraints within the parameter space. GAs, leveraging the selection operator, mimic natural organisms in competitive settings, where only the most skilled individuals and their offspring persist. The GA search's evolutionary journey pivots on two essential facets: exploration and exploitation. Exploration, catalyzed by genetic operators such as mutation (with a minor probability Mu) and crossover (with probability CS), nurtures population diversity by exploring the search space. Crossover concocts new offspring by merging genetic data from two parent chromosomes, while mutation entails the random alteration of gene values in a parent chromosome. Exploitation, conversely, limits population diversity by selecting topperforming individuals at every stage. To safeguard the continuity of the fittest individuals in ensuing generations, an elitist strategy is frequently integrated, especially if they don't survive the selection process. Here, the parameter p is used to denote the ratio of elitists in upcoming generations. Finally, the GA algorithm with elitist strategy applied in this study is delineated in Algorithm 2.

Algorithm 2: Genetic algorithms

| | |
|---|---|
| 1. | Input: Nₚ, Mu, MaxG, CS, ρ |
| 2. | Generate an initial population of size Nₚ |
| 2(a) | Evaluate the fitness of each individual. |
| 2(b) | Sort the population by fitness Determine the number of elites, E = floor (Nₚ × ρ) |
| 2(c) | Create a new population, starting with the E. |
| 2(d) | While size of new population < Nₚ do: b. Select two parents with defined selection |
| | strategy (e.g., roulette wheel, tournament) c. Perform crossover between the two |
| | parents using the specified crossover strategy CS to create two offspring. d. Mutate |
| | the offspring at each position with probability Mu. e. If the offspring does not meet |
| | constraints, modify until it does. f. Add the offspring to the new population. |
| | end while |
| 3. | Replace the current population with the new population. |
| 4. | end for MaxG |
| 5. | Return the best individual and its fitness from the final population. |

### RL/GA Based Optimization of Detectors' Location in BEAVR Benchmark

RL algorithms including PPO, DQN, MCTS and A2C are employed to optimize the configuration of in-core detectors. The goal is to achieve the most favorable arrangement that results in the highest power reconstruction accuracy. For comparison, the GA is also utilized to solve this optimization problem, serving as a baseline against which the results of the RL algorithms can be evaluated. FIG. 5 graphically represents the RL based optimization framework for in-core detector configuration. The process begins by defining the state space, which is the search area, from an engineering and safety perspective. Subsequently, the number of detectors is determined based on economic considerations. A crucial part of this framework is the definition of the reward function, which informs three key tasks integral to resolving the optimization problem: a) Dataset Generation: The primary aim is to develop an online power reconstruction system predicated on the generated dataset. This system also provides reference data for assessing the environment, enabling the allocation of rewards at each action step. b) Power Reconstruction System Development: The Proper Orthogonal Decomposition (POD) algorithm is employed to establish a power reconstruction system, thereby enhancing data processing capabilities. c) Execution of Detector Position Optimization: This phase entails the application of RL algorithms to the predefined customized environment, which is built on the outcomes of the initial two stages. It's important to note that for GA, only the reward function or the fitness function needs to be defined. The determined reward/fitness function plays a crucial role as it steers the optimization process towards solutions that not only maximize system performance but also comply with PDRS criteria.

### Generation of Dataset

Validity of RL/GA based optimization of the location of in-core detectors is ascertained through the employment of the BEAVRS benchmark (Horelik et al., 2013). It characterizes a 4-loop Westinghouse power plant in meticulous detail, including in-core fission detectors and fuel assemblies. BEAVRS provides an opportunity for analysts to build highly precise reactor core models to validate the neutron transport simulations. It offers a comprehensive representation of a PWR core, covering aspects such as geometry, material specifications, and operational data. This research employs OpenMC (Romano et al., 2015) to simulate power distribution profiles under various reactor states in BEAVRS. The resulting data provides a reference for flux distribution, as well as a basis for the simulation of detector measurements. Importantly, while the BEAVRS core does not possess an in-core fixed detector, this benchmark serves as a critical validation platform for the proposed optimization framework. For the purpose of this study, 58 potential detector locations within the BEAVRS core have been identified from an engineering perspective, offering a suitable search space for the methodologies described in this paper. In addition to these pre-selected locations, the present work outlines a broader technical pathway that contemplates a larger search space encompassing 193 potential detector placements, corresponding to the total number of assemblies in the reactor core with mechanical installation requirements and safety considerations. The core optimization process adheres consistently to the procedure initially applied to the search space of 58 locations, ensuring the robustness and adaptability of the framework. Simulating various operational conditions is to ensure the optimized detector placement yield high 3D reconstructed power distribution under various operational conditions, which is especially beneficial for advanced reactors. Compared to factors such as fuel depletion and boron concentration, the movement of control rods within the reactor core exerts a significant impact on the flux distribution, particularly its shape (Anupreethi et al., 2020). Additionally, the number of control rods inserted in the core reflects different operational phases of the reactor. Consequently, the study manipulates the positioning of control rods to generate diverse flux distributions within the reactor core. However, the benchmark presently lacks a Monte Carlo simulation for control rod movement. Therefore, the study also developed a simulation function for the benchmark to simulate the control rod movement.

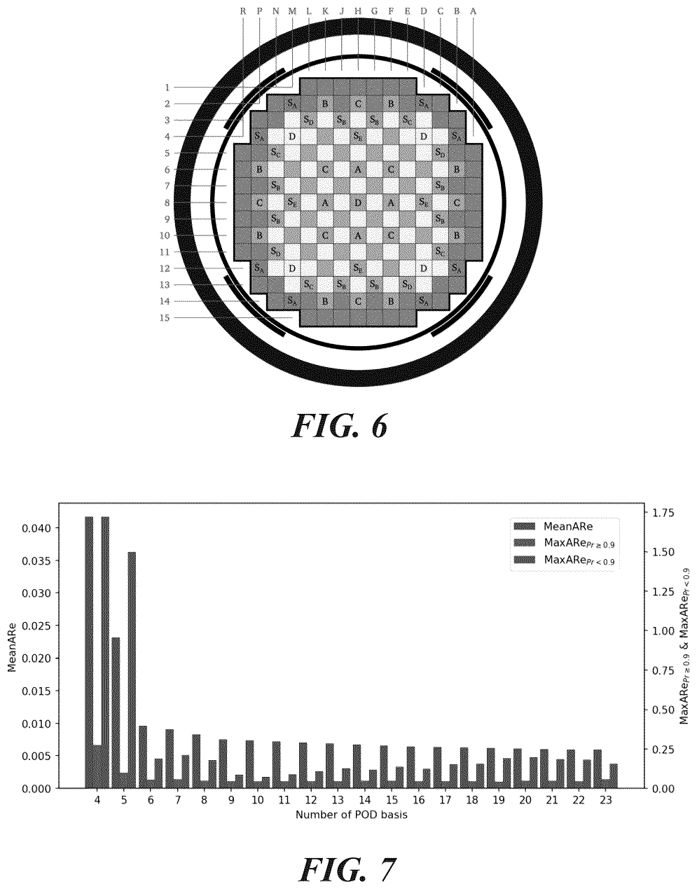

FIG. 6 illustrates the radial locations of control rod clusters pertaining to each control rod bank (A, B, C, D) and shutdown bank (SA, SB, SC, SD, SE). To generate a diverse set of flux distribution scenarios, the study includes an adjustment scheme for the number and position of control rods within the reactor core, in which there are a total of 4 control rod modes: 4, 8, 12, and 24 control rods are randomly selected. Assuming that all 24 control rods are inserted into the core in the initial state, each individual control rod in each modes has two states: fully inserted and fully withdrawn. Under such random combinations, a total of 400 different combinations of control rod states are selected, and OpenMC is used to simulate the reactor core under these conditions to get the power distribution. To achieve an optimized detector placement distribution that ensures high reconstruction accuracy in both radial and axial directions for the power reconstruction system, the reactor is divided axially into six sections, Z1, Z2, Z3, Z4, Z5, Z6, with each of the 193 radial assemblies considered a separate area, and the power values at each nodes can be obtained by OpenMC. The node power value can be reconstructed by using the measurements of detector in the corresponding axial region shown in FIG. 3. Within each axial region, the example implementation employed RL algorithms and GA to obtain the optimal radial distribution of detectors. The final detector distribution is composed of the union of the detector distributions from these six regions.

### Developing a PDRS Based on Proper Orthogonal Decomposition

This study developed a power reconstruction system for the reactor in BEAVRS based on proper orthogonal decomposition (POD) method. According to the prevailing consensus in the literature, there are specific standards that must be met during the operation of reactor. These standards stipulate that the maximum relative error for each node adding up to 1158 (6*193) in this work-should not exceed 5% at nodes where the relative power is greater than 0.9. For nodes with relative power less than 0.9, this maximum relative error threshold is slightly higher, at 8%. These calculations are based on detector readings used for power reconstruction (Wang et al., 2011). To verify this new developed power reconstruction system, the study randomly selected 50 configurations of power distribution from 400 power configurations, which covers the full range of the operation, and using the information from 58 detectors, distributed in the reactor core and shown in FIG. 1(a), to reconstruct the power distribution and calculate the power reconstruction error for each assembly. The study used both Mean Absolute Relative error, MeanARe, and Maximum Absolute Relative error, MaxARe, as evaluation metrics for each layer, which are defined as follows:

$$Mean ARe = \frac{1}{N} {\sum }_{i = 1}^{N} \vert \frac{{p}_{i}^{p r e} - {p}_{i}}{{p}_{i}} \vert \qquad ( 14 )$$

$$Max ARe = Max \{ {\vert \frac{{p}_{i}^{p r e} - {p}_{i}}{{p}_{i}} \vert}_{i = 1 , 2 , 3 … N} \} \qquad ( 15 )$$

In which N is the number of nodes, pi is the reference from OpenMC, and pᵢ^{pre} is reconstruction node power from proposed method. FIG. 7 illustrates the error in reconstructing the 3D power distribution under varying numbers of POD basis. In this figure, MaxARe e_{Pr≥0.9} represents the maximum absolute relative error for nodes where the relative power is higher than 0.9, while MaxARe_{Pr<0.9} is the same for nodes with a relative power less than 0.9. A clear observation from the figure is the inverse relationship between MeanARe values and the number of POD bases—as the number of POD bases increases, MeanARe values decrease. Interestingly, the MaxARe values do not exhibit a direct correlation with the number of POD bases, highlighting the complexity of this relationship. Considering the reconstruction accuracy, efficiency, acceptable standard, 10 can be chose as the POD number and the power reconstruction system with this number of basis is used to conduct the reward/fitness function for RL and GA. For 50 chosen power distribution cases and each case includes six axial regions or six layers (1158 nodes for each case), the power reconstruction system with 10 POD basis yielded a MeanARe of 0.74%, MaxARe_{Pr≥0.9} of 4.4%, and MaxARe e_{Pr<0.9} of 7.5%, which are well within the acceptable range as per the established criterion.

Optimization of Detectors' Location with RL and GA

Identifying the optimal in-core detector placement is a multi-objective problem, as an ideal configuration should minimize MeanARe and keep MaxARe P_{Pr≥0.9} and MaxARe_{Pr<0.9} low than certain value. Lower MeanARe values indicate better performance of the PDRS, while MaxARe values are related to safety considerations. The objective function for RL/GA in this study is constructed using weighted scalarization, a method extensively employed for a multi-objective problem in prior research (Nasr et al., 2019; Zameer et al., 2020, Radaideh et al., 2022), which is shown as

$${Max}_{Y} Reward ( Y ) = \frac{1}{\begin{matrix}{w}_{1} * Mean ARe ( Y ) + \\ {w}_{2} * Max {ARe}_{P r \geq 0.9} ( Y ) + {w}_{3} * Max {ARe}_{P r < 0.9} ( Y )\end{matrix}} \qquad ( 16 )$$

in which, w represents the corresponding weight as determined by the analyst, based on prior experience and initial convergence tests, while Y is a layout of detectors. Taking into account the criteria for power reconstruction system evaluation and the convergence of RL and GA, the values of w₁ and w₃ are both set as 1. During the training process, it has been observed that MaxARee_{Pr≥0.9} generally meets the required standards with relative ease. The study found that MaxARee_{Pr≥0.9} can meet the criteria definitely when MaxARee_{Pr<0.9} has already done. Hence, the objective function is defined as following

$${Max}_{Y} Reward ( Y ) = \frac{1}{Mean ARe ( Y ) + Max {ARe}_{P r < 0.9} ( Y )} \qquad ( 17 )$$

Besides, the power distribution error can only be obtained when all of the fixed number of detectors are installed in the reactor core, hence, there exist a sparse reward issue. Therefore, in order to reduce the influence of sparse reward on the convergence of RL algorithms, two primary forms of rewards are dispensed before the completion of detector placement, i.e., the round is not yet finished. The first scenario arises when an agent designates an action, a selected position, to place a detector where one already exists. Such actions, considered non-compliant, yield a negative reward for the agent. The second scenario occurs when an agent's action aligns with the rules, but the game has not concluded. In such instances, the reward returned to the agent equals the multiple of the variance value at the selected position because literatures suggest that positions with higher variance have a more pronounced impact on power distribution reconstruction (Oh et al., 1994; Bahuguna et al., 2023; Anupreethi et al., 2020; Argaud et al., 2018) and the variance of such chosen positions indirectly reflects the quality of the agent's selected action. However, the setting of this reward is also constrained by the limitations of the variance method, impacting the optimal convergence values of both RL and GA methods. Empirical tests of algorithmic convergence have shown that quintupling the variance as a reward can significantly improve algorithmic convergence. Finally, the reward/objective function is defined as

$${Max}_{Y} Reward ( Y ) = \{ \frac{1}{\begin{matrix}Mean ARe ( Y ) + Max A {Ree}_{Pr < 0.9} ( Y ) \\ Var ( {Y}_{i} )\end{matrix}} , - 1 ,$$

$${\sum }_{i = 1}^{N} {Y}_{i} = M$$

$${\sum }_{i = 1}^{N} {Y}_{i} < M$$

the selected location already has a detector placed

From the definition of the objective function, it can be inferred that maximizing the reward implies minimizing the MeanARe and MaxARe Pr²0.9. More complex segmented reward functions were also experimented with in the study. However, during the training process, it was found that these complex reward functions can pose challenges to the convergence of all four methods, particularly for DQN and A2C.

In this study, the action space is a discrete variable of 58 potential locations (each action is a location of detector) and the state space is an array of size 58×1. It is worthy mentioned that the positions of each assembly including detector locations, are sequentially numbered which will effectively simplify a two-dimensional detector positioning optimization problem into a one-dimensional optimization task, where both the action and state spaces are transformed into one-dimensional vectors. This reduction in complexity greatly benefits the construction of custom environments and facilitates more manageable optimization procedures. The strategic approach to this problem, using RL, can be encapsulated as follows:
1. Each episode of the game commences in a consistent manner: beginning with the layout of possible locations for detectors (initially, no detectors are installed). The RL agent receives the current state and scalar reward as input, and accordingly determines the most suitable action to undertake (i.e., choosing among 58 potential locations). Upon the execution of this action in the given environment, the resultant reward calculated by Eq. (18) and subsequent state are relayed back to the RL algorithm, setting off the next iteration of the loop.
2. Step 1 is repeated until all fixed number of detectors are put in the reactor core. Then PDRS is activated, and the reward is calculate using Eq. (18).
3. The procedures outlined in steps 1 and 2 continue in a loop until all the TS are completed.

A thorough investigation encompassing a range of architectures, including deeper and wider networks are conducted. Ultimately, the two-layer 64-node architecture emerged as the optimal choice in our specific task from the perspective of the trade-off in network complexity and computational resource efficiency. For the GA algorithm, each individual is represented by a 58×1 vector and M positions in this vector are marked with a ‘1’, indicating the placement of a detector, while the remaining positions, marked with ‘0’, indicate that no detector is placed. To finalize the configuration, 154,000 episodes is implemented for RL indicating 154,000 runs of the power reconstruction system. These runs are organized into batches of 200, resulting in a total of 200 training epochs for RL. On the other hand, for GA, an average of 7.7 generations (each generation includes 100 individuals, implying 100 runs of the power reconstruction system are needed to evaluate one generation) are considered as one epoch. This configuration ensures that all algorithms, irrespective of their type, have an equal number of interactions with PDRS.

### Result and Discussion

This study utilized stable-baselines3 (Raffin et al., 2021) for implementing the DQN, A2C, and PPO algorithms. To optimize the hyperparameters of the five algorithms under consideration, the study adopted a grid search approach. This ensured fair comparisons by maximizing the performance of each algorithm. The hyperparameter tuning process mainly comprised two steps: 1) Defining initial ranges for hyperparameters, influenced by academic recommendations and user experiences. 2) Considering the sensitivity of parameters: those parameters with higher sensitivity were given more detailed nodes. Each combination of hyperparameters was evaluated based on the convergence of the maximum reward at each epoch. The final optimized hyperparameters for the five methods used to optimize the Z 1 layer are displayed in Table 1. This approach allowed for the most effective use of each algorithm in optimizing the configuration of in-core detectors.

TABLE 1
Optimal hyperparameters for all methods

| PPO | | DON | | A2C | | MCTS | | GA | |
|---|---|---|---|---|---|---|---|---|---|
| Item | Value | Item | Value | Item | Value | Item | Value | Item | Value |
| γ | 0.99 | γ | 0.99 | γ | 0.99 | Time | 1105 s | Mu | 0.0001 |
| | | | | | | limit | | | |
| λ | 1 | τ | 0.02 | λ | 1 | κ | 0.75 | MaxG | 1540 |
| CLIP | 0.45 | εᵢₙᵢₜ | 1 | VF_{coef} | 0.5 | | | CS | 1 |
| VF_{coef} | 0.5 | ε_{final} | 0.01 | ENT_{coef} | 0.05 | | | ρ | 0.1 |
| ENT_{coef} | 0.05 | Lr | 0.0001 | lr | 0.0002 | | | | |
| lr | 0.0001 | Bu | 500000 | MGGnorm | 0.5 | | | | |
| B | 192 | B | 256 | Fₜᵣₐᵢₙ | 8 | | | | |
| Fₜᵣₐᵢₙ | 8 | LS | 5000 | | | | | | |
| | | Fₜᵣₐᵢₙ | 8 | | | | | | |

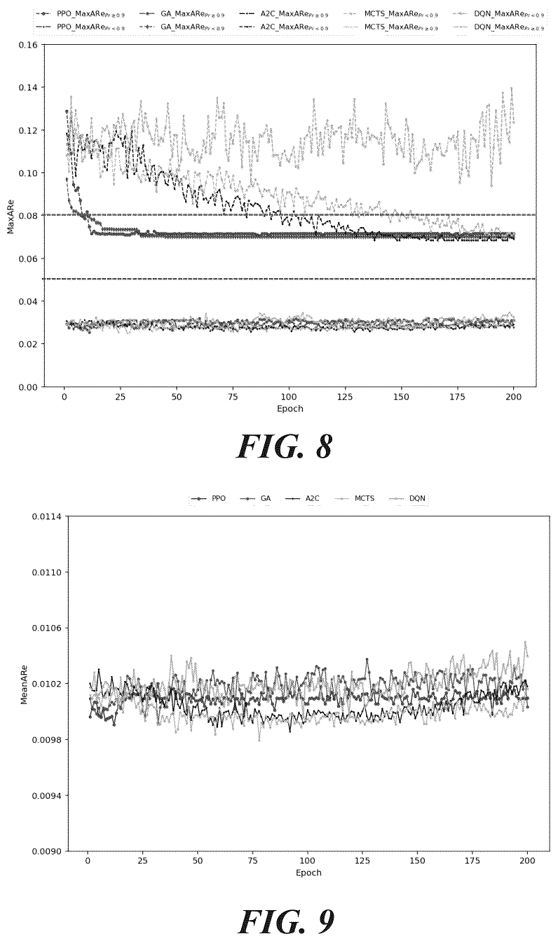

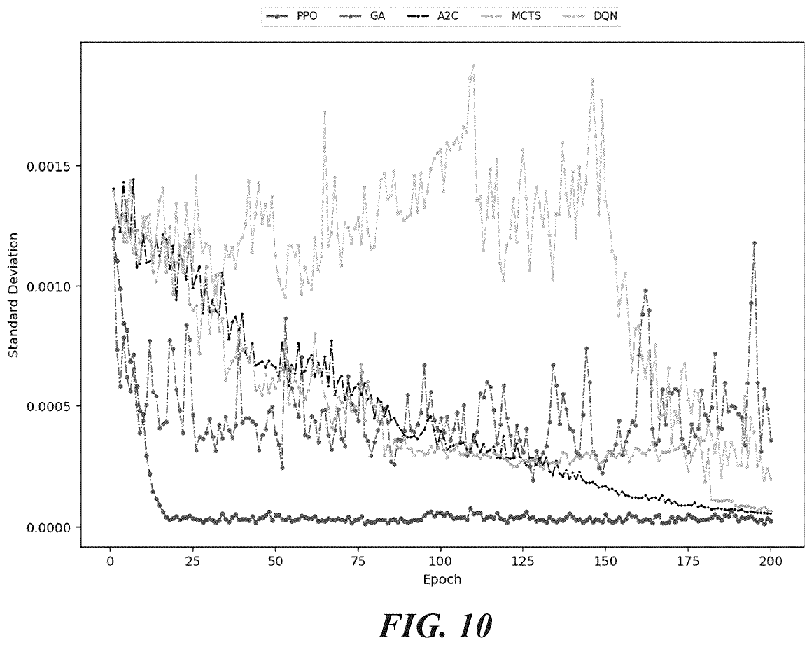

A special number of selected positions is 25 for each axial region in the study. This selective number is just for verifying our framework and the number of detectors is determined from an engineering and economic perspective in finding an optimal in-core detector layout. Besides, this proposed framework can also be used to generate optimal solutions for different number of detectors and provide the reference of designing the in-core detector configuration for engineer. Finally, the optimal layout with a fixed number of detectors by four methods is sought. FIG. 8 demonstrates the changing patterns of MaxARe e_{Pr≥0.9} and MaxARe_{Pr<0.9} for five methodologies during the entire training process for the Z1 layer. FIG. 8 further illustrates the example criteria that the solutions generated by the five methods should meet, i.e., MaxARe_{Pr≥0.9} should not exceed 5%, and MaxARe_{Pr<0.9} should be below 8%. As can be discerned from FIG. 8, PPO and GA nearly identify feasible solutions simultaneously, with their solution discovery rate surpassing that of A2C and MCTS. DQN, however, appears unable to converge or identify feasible solutions under the given parameters. A potential limitation observed is that the smaller neural network size of [64,64] may not be optimal for DQN. This can require further exploration to determine the ideal neural network size and hyperparameter configurations for DQN. While this study does not showcase all implementations, such as trials with varying neural network sizes and parameter adjustments, many results may not meet the desired criteria. Even though some outcomes from DQN with larger neural network sizes outperformed their smaller counterparts, maintaining a consistent neural network structure can be used for a fair comparison across different RL algorithms. FIG. 9 illustrates the variation trend of MeanARe for the five methods when optimizing the Z1 layer throughout the epochs. It can be inferred from this figure that among feasible solutions in the study, MCTS achieves the most optimal solution, followed by A2C, then PPO, with GA being the last, but it might converge more slowly than these alternatives. Besides, a salient benefit of MCTS is its limited dependence on hyperparameter tuning. With just two primary hyperparameters typically requiring adjustment, the process becomes significantly more streamlined and user-friendly compared to the more labor-intensive tuning required for other methods. This case in hyperparameter optimization makes MCTS particularly attractive for the engineering applications. Moreover, to address its relatively slower convergence, there have been advances in MCTS methodologies. Notably, versions that harness the power of deep neural networks at each tree search step, drawing inspiration from milestones like AlphaGo, shift from traditional random simulation to a more informed strategy for tree expansion and state evaluations. FIG. 10 portrays the trend of standard deviation of MeanARe with respect to epochs for the optimization of Z1 layer. It can be observed that under the specified parameters, GA and DQN appear to exhibit convergence issues, which could potentially make these two algorithms susceptible to falling into local optima (Radaidch et al., 2022). Meanwhile, it can be discerned that PPO exhibits the fastest convergence rate among the five methods.

GA and RL strategies are similarly utilized to determine the optimal detector locations for five other axial regions, with the objective of maintaining precise reconstruction accuracy in both radial and axial directions of the reactor core. Additionally, a grid search method is employed to pinpoint the optimal parameters for each axial region. It's important to note that the optimal parameters for the Z1 layer could serve as the ideal initial parameters for other layers. This is attributed to the comparable nature of the radial power distribution across each layer. Consequently, this similarity significantly aids in the tuning of parameters for the proposed methods across other layers. Tables 2 presents the optimal detector arrangements for six axial regions, as optimized by four methods, along with the corresponding reconstruction error achieved under these layouts. It is noteworthy that, as FIG. 5 shows DQN's inability to find a feasible solution under the specified parameters, our subsequent analysis of results will focus on the remaining four methods. From Table 2, it is shown that the quality of the best solutions generated by the four methods is comparable, i.e., the MeanAR values are roughly similar. However, PPO generates solutions with lower MaxARe_{Pr<0.9} to the other three methods, indicating that the feasible solutions generated by this method have a larger safety margin. It should be noted that none of the methods as applied in this study were able to achieve satisfactory results for the example Z6 modelling, hence the absence of these results in Table 2.

TABLE 2
51]
Calculation results among three studied methods

| Methods | | Z1 | Z2 | Z3 | Z 4 | Z5 |
|---|---|---|---|---|---|---|
| PPO | MeanARe * A2C | 1.01 | 0.69 | 0.62 | 0.63 | 0.78 |
| | MaxARe_{Pr≥0.9} | 2.99 | 3.51 | 4.14 | 3.31 | 3.98 |
| | MaxARe_{Pr<0.9} | 7.59 | 6.31 | 7.89 | 7.89 | 7.95 |
| | MaxARe_{Pr≥0.9} | 3.62 | 4.34 | 3.48 | 3.58 | 4.59 |
| | MaxARe_{Pr<0.9} | 7.91 | 6.99 | 7.96 | 6.96 | 7.93 |
| | MaxARe_{Pr≥0.9} | 3.57 | 4.37 | 3.91 | 3.65 | 3.76 |
| | MaxARe_{Pr<0.9} | 7.72 | 7.23 | 7.23 | 7.80 | 7.89 |
| GA | MeanARe * | 1.02 | 0.69 | 0.63 | 0.62 | 0.78 |
| | MaxARe_{Pr≥0.9} | 3.19 | 3.73 | 3.32 | 3.72 | 4.81 |
| | MaxARe_{Pr<0.9} | 7.91 | 6.83 | 7.87 | 7.29 | 8.00(7.988) |

A possible explanation for this could be that when the number of detectors drops below a certain threshold, it severely affects the precision of the reconstruction system. This can be because the precision of the reconstruction system is influenced by two aspects: the number of detectors and the layout of the detectors. Nevertheless, the optimal layouts found for the current five layers, after undergoing a union operation and subsequent filtering, ultimately result in detector arrangements that meet the reconstruction precision requirements. Subsequent result analysis also substantiates this point. Table 3 presents the feasible solutions, i.e., the detector position distributions that meet the standard generated by each method within a fixed number of time steps for the Z1 layer. It can be observed that A2C is capable of producing a greater number of feasible solutions.

TABLE 3
The number of feasible patter of detectors'
location among four methods

| Method | PPO | A2C | MCTS | GA |
|---|---|---|---|---|
| Number of Feasible Patterns | 845 | 3937 | 1030 | 1017 |

TABLE 4
The reconstruction error of the final detectors'
configuration among four methods (unit: %)

| Methods | MeanARe | MaxARe_{Pr<0.9} | MaxARe_{Pr<0.9} |
|---|---|---|---|
| PPO | 0.75 | 7.85 | 4.04 |
| A2C | 0.76 | 7.71 | 4.16 |
| MCTS | 0.76 | 7.86 | 3.64 |
| GA | 0.76 | 7.92 | 4.00 |

To ensure that the power reconstruction accuracy of each axial region meets the requirements, the study ultimately chose to place detectors at 40 positions. These 40 positions are the result of the superimposition of the selected positions across five axial regions. However, for each method, the total number of final positions obtained by the superimposition of positions across the six regions may exceed 40. To maintain 40 positions, the following steps are mainly carried out: a) For the detector layout produced by each method for each layer, there are many layouts that meet the requirements. The example implementation aimed to select the layout with a higher similarity to the other layers, while also considering accuracy, b) Based on step 1, the study counted the frequency of each selected position and sort them, accordingly, retaining only the top 40 positions with the highest frequency. It merits attention that within the study, the optimization process was bifurcated, i.e., arriving at the ultimate detector layout, into two distinct phases.

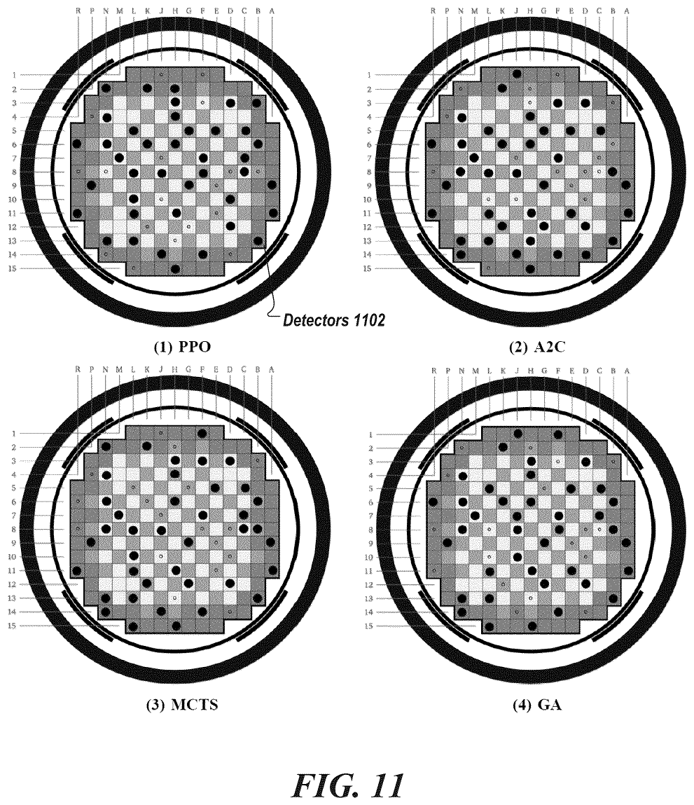

Initially, the study utilized RL algorithms to discern optimal detector positions within six axial regions, followed by subsequent amalgamation via selection. Notably, the study eschewed the direct merging of all six regions into a single zone wherein each reward encapsulates the reconstruction errors of all nodes. This approach is guided by several rationales: a) if the reward bestowed upon the agent encompasses the reconstruction errors of all nodes, it results in an excessively intricate reward function. Such complexity proves detrimental to the convergence of the RL algorithm. Empirical evidence gleaned from algorithmic implementation indicates that simple reward functions facilitate effortless parameter tuning and yield swift convergence. It is also observed that optimal parameters for RL models across different axial regions exhibit marginal variations; b) in the course of the two-step optimization process, it is feasible to incorporate certain constraints, such as mechanical installation and safety considerations, into the optimal detector layout. This is particularly pertinent in scenarios where potential detector positions are not pre-determined, and the search space encompasses 193 instead of 58 locations. For instance, during the secondary selection phase, criteria such as symmetry and the distance of chosen detector positions from the reactivity device can be incorporated (Anupreethi, et al., 2020). This structure enables the example implementation to deliver an optimized detector layout that conforms to various physical and safety constraints, offering an approach that is both theoretically robust and practically viable. Additionally, the study can also craft a RL environment to facilitate the selection of detector positions, considering factors such as safety and mechanical installation. This can be done, for instance, by marking the locations of mechanical installations and penalizing the RL agent for choosing detector positions close to these marked areas. Table 4 and FIG. 11 show the results of final detectors' configuration based on the four methods. It can be observed that, based on this selection method, the computational results of all optimization algorithms can satisfy the requirements for reconstruction accuracy.

### Discussion

Additional supporting results were collected for the example implementation. as described in the below additional tables A1-A4.

TABLE A1
Optimal detector layout for Z1 and Z2 regions in
the vertical direction based on four methods.

| Z1 | | | | Z2 | | | |
|---|---|---|---|---|---|---|---|
| PPO | A2C | MCTS | GA | PPO | A2C | MCTS | GA |
| J14 | J14 | J14 | J14 | J14 | J14 | J14 | L15 |
| F14 | F14 | F14 | F14 | F14 | F14 | F14 | N14 |
| N13 | N13 | N13 | N13 | N13 | N13 | N13 | J14 |
| L13 | B13 | B13 | B13 | B13 | B13 | B13 | F14 |
| B13 | K12 | K12 | K12 | D12 | D12 | D12 | B13 |
| D12 | D12 | D12 | D12 | R11 | R11 | R11 | D12 |
| R11 | R11 | R11 | A11 | L11 | L11 | L11 | L11 |
| H11 | E11 | H11 | P9 | E11 | E11 | J10 | J10 |
| A11 | A11 | A11 | G9 | J10 | J10 | P9 | P9 |
| G9 | G9 | G9 | N8 | G9 | P9 | A9 | G9 |
| N8 | N8 | N8 | J8 | A9 | G9 | L8 | A9 |
| L8 | J8 | J8 | F8 | J8 | A9 | J8 | J8 |
| J8 | J7 | B8 | J7 | F8 | L8 | F8 | C8 |
| B8 | C7 | J7 | C7 | B8 | J8 | C8 | M7 |
| J7 | K6 | C7 | N6 | M7 | D8 | M7 | F7 |
| C7 | H6 | K6 | H6 | F7 | M7 | F7 | K6 |
| K6 | L5 | B6 | B6 | C7 | F7 | L5 | B6 |
| B6 | G5 | E5 | R6 | N6 | L5 | E5 | L5 |
| E5 | E5 | C5 | E5 | H6 | E5 | C5 | E5 |
| C5 | C5 | N4 | C5 | E5 | C5 | N4 | C5 |
| N4 | N4 | H4 | N4 | N4 | N4 | H3 | N4 |
| H4 | H4 | H3 | H4 | H4 | H3 | D3 | H4 |
| H3 | D3 | D3 | D3 | D3 | D3 | B3 | D3 |
| D3 | K2 | H2 | N2 | K2 | J1 | N2 | K2 |
| F1 | F1 | F1 | F1 | H2 | F1 | H2 | H2 |

TABLE A2
Optimal detector layout for Z3 and Z4 regions in
the vertical direction based on four methods.

| Z3 | | | | Z4 | | | |
|---|---|---|---|---|---|---|---|
| PPO | A2C | MCTS | GA | PPO | A2C | MCTS | GA |
| H15 | H15 | H15 | J14 | L15 | L15 | L15 | L15 |
| J14 | N14 | F14 | N13 | H15 | H15 | H15 | H15 |
| N13 | J14 | N13 | L13 | F14 | F14 | F14 | F14 |
| L13 | N13 | L13 | B13 | D14 | D14 | N13 | D14 |
| B13 | L13 | H13 | G12 | N13 | N13 | L13 | N13 |
| D12 | H13 | B13 | D12 | L13 | L13 | B13 | L13 |
| R11 | B13 | D12 | L11 | D12 | B13 | G12 | D12 |
| L10 | D12 | R11 | H11 | L11 | G12 | D12 | L11 |
| D10 | E11 | H11 | A11 | H11 | D12 | E11 | H11 |
| G9 | A11 | L10 | P9 | A11 | L11 | L10 | D10 |
| A9 | L10 | E9 | J8 | P9 | H11 | G9 | P9 |
| L8 | E9 | L8 | B8 | A9 | P9 | A9 | G9 |
| J8 | N8 | J8 | J7 | J8 | G9 | R8 | A9 |
| C7 | J8 | B8 | F7 | B8 | A9 | L8 | J8 |
| N6 | B8 | N6 | N6 | M7 | J8 | J8 | F7 |
| K6 | N6 | K6 | K6 | F7 | B8 | M7 | C7 |
| H6 | H6 | H6 | H6 | N6 | F7 | F7 | N6 |
| L5 | R6 | L5 | B6 | B6 | N6 | C7 | B6 |
| G5 | L5 | G5 | R6 | L5 | L5 | L5 | L5 |
| N4 | G5 | C5 | L5 | C5 | E5 | C5 | C5 |
| D3 | C5 | N4 | N4 | N4 | N4 | N4 | N4 |
| N2 | N4 | H4 | H4 | H3 | H4 | H4 | H3 |
| K2 | D3 | D3 | D3 | D3 | D3 | F3 | D3 |
| H2 | J1 | K2 | J1 | B3 | K2 | D3 | K2 |
| F1 | F1 | H2 | F1 | F1 | F1 | K2 | F1 |

TABLE 3
Optimal detector layout for Z5 region in the
vertical direction based on four methods.

| PPO | A2C | MCTS | GA |
|---|---|---|---|
| L13 | N13 | L13 | N13 |
| H13 | H13 | K12 | L13 |
| B13 | K12 | G12 | B13 |
| K12 | G12 | D12 | G12 |
| G12 | D12 | L11 | D12 |
| D12 | L11 | A11 | L11 |
| H11 | H11 | L10 | H11 |
| A11 | A11 | D10 | E11 |
| L10 | L10 | G9 | A11 |
| G9 | G9 | A9 | G9 |
| A9 | L8 | J8 | A9 |
| L8 | J8 | M7 | J8 |
| J8 | B8 | J7 | F8 |
| F8 | M7 | F7 | B8 |
| B8 | N6 | H6 | M7 |
| M7 | K6 | B6 | F7 |
| N6 | H6 | RG | N6 |
| R6 | R6 | L5 | K6 |
| E5 | E5 | E5 | C5 |
| C5 | C5 | C5 | N4 |
| N4 | N4 | P4 | H4 |
| D3 | F3 | N4 | H3 |
| B3 | B3 | F3 | F3 |
| J1 | J1 | D3 | B3 |
| F1 | F1 | B3 | H2 |

TABLE 4
The final location of detectors among four methods.

| PPO | A2C | MCTS | GA |
|---|---|---|---|
| H15 | H15 | L15 | L15 |
| J14 | N14 | H15 | H15 |
| F14 | J14 | N14 | N14 |
| N13 | F14 | J14 | F14 |
| L13 | N13 | F14 | N13 |
| B13 | L13 | N13 | L13 |
| D12 | H13 | L13 | B13 |
| R11 | B13 | B13 | G12 |
| L11 | K12 | K12 | D12 |
| H11 | G12 | G12 | L11 |
| A11 | D12 | D12 | H11 |
| L10 | R11 | R11 | E11 |
| D10 | L11 | L11 | A11 |
| P9 | H11 | H11 | J10 |
| G9 | E11 | A11 | P9 |
| A9 | A11 | L10 | G9 |
| L8 | P9 | P9 | A9 |
| J8 | G9 | G9 | N8 |
| F8 | D14 | A9 | J8 |
| B8 | F3 | C8 | F8 |
| M7 | A9 | L8 | B8 |
| F7 | N8 | J8 | M7 |
| C7 | L8 | B8 | J7 |
| N6 | J8 | M7 | F7 |
| K6 | B8 | N6 | C7 |
| H6 | M7 | F7 | N6 |
| B6 | F7 | C7 | K6 |
| R6 | N6 | N8 | H6 |
| L5 | K6 | H6 | B6 |
| G5 | H6 | B6 | R6 |
| E5 | R6 | E5 | L5 |
| C5 | L5 | C5 | E5 |
| N4 | G5 | N4 | C5 |
| H4 | E5 | H4 | N4 |
| H3 | C5 | H3 | H4 |
| D3 | N4 | F3 | H3 |
| B3 | H4 | D3 | D3 |
| N2 | D3 | N2 | K2 |
| K2 | K2 | K2 | J1 |
| H2 | J1 | F1 | F1 |

It is to be understood that the methods and systems are not limited to specific synthetic methods, specific components, or particular compositions. It is also to be understood that the terminology used herein is for the purpose of describing particular implementations only and is not intended to be limiting.

Various computing systems may be employed to implement the exemplary system and method described herein. The computing device may comprise two or more computers in communication with each other that collaborate to perform a task. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. In an embodiment, virtualization software may be employed by the computing device to provide the functionality of a number of servers that is not directly bound to the number of computers in the computing device. For example, virtualization software may provide twenty virtual servers on four physical computers. In an embodiment, the functionality disclosed above may be provided by executing the application and/or applications in a cloud computing environment. Cloud computing may comprise providing computing services via a network connection using dynamically scalable computing resources. Cloud computing may be supported, at least in part, by virtualization software. A cloud computing environment may be established by an enterprise and/or maybe hired on an as-needed basis from a third-party provider. Some cloud computing environments may comprise cloud computing resources owned and operated by the enterprise as well as cloud computing resources hired and/or leased from a third-party provider.

In its most basic configuration, a computing device typically includes at least one processing unit and system memory. Depending on the exact configuration and type of computing device, system memory may be volatile (such as random-access memory (RAM)), non-volatile (such as read-only memory (ROM), flash memory, etc.), or some combination of the two. The processing unit(s) may be a standard programmable processor that performs arithmetic and logic operations necessary for the operation of the computing device. As used herein, processing unit and processor refers to a physical hardware device that executes encoded instructions for performing functions on inputs and creating outputs, including, for example, but not limited to, microprocessors (MCUs), microcontrollers, graphical processing units (GPUs), and application-specific circuits (ASICs). Thus, while instructions may be discussed as executed by a processor, the instructions may be executed simultaneously, serially, or otherwise executed by one or multiple processors. The computing device 200 may also include a bus or other communication mechanism for communicating information among various components of the computing device.

The computing device may have additional features/functionality. For example, computing devices may include additional storage such as removable storage and non-removable storage including, but not limited to, magnetic or optical disks or tapes. The computing device may also contain network connection(s) that allow the device to communicate with other devices, such as over the communication pathways described herein. The network connection(s) may take the form of modems, modem banks, Ethernet cards, universal serial bus (USB) interface cards, serial interfaces, token ring cards, fiber distributed data interface (FDDI) cards, wireless local area network (WLAN) cards, radio transceiver cards such as code division multiple access (CDMA), global system for mobile communications (GSM), long-term evolution (LTE), worldwide interoperability for microwave access (WiMAX), and/or other air interface protocol radio transceiver cards, and other well-known network devices. The computing device may also have input device(s) 270 such as keyboards, keypads, switches, dials, mice, trackballs, touch screens, voice recognizers, card readers, paper tape readers, or other well-known input devices. Output device(s) 260 such as printers, video monitors, liquid crystal displays (LCDs), touch screen displays, displays, speakers, etc., may also be included. The additional devices may be connected to the bus in order to facilitate the communication of data among the components of the computing device. All these devices are well known in the art and need not be discussed at length here.

The processing unit may be configured to execute program code encoded in tangible, computer-readable media. Tangible, computer-readable media refers to any media that is capable of providing data that causes the computing device (i.e., a machine) to operate in a particular fashion. Various computer-readable media may be utilized to provide instructions to the processing unit for execution. Example tangible, computer-readable media may include but is are not limited to volatile media, non-volatile media, removable media, and non-removable media implemented in any method or technology for storage of information such as computer-readable instructions, data structures, program modules, or other data. System memory, removable storage, and non-removable storage are all examples of tangible computer storage media. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In light of the above, it should be appreciated that many types of physical transformations take place in the computer architecture in order to store and execute the software components presented herein. It also should be appreciated that the computer architecture may include other types of computing devices, including hand-held computers, embedded computer systems, personal digital assistants, and other types of computing devices known to those skilled in the art.

In an example implementation, the processing unit may execute program code stored in the system memory. For example, the bus may carry data to the system memory, from which the processing unit receives and executes instructions. The data received by the system memory may optionally be stored on the removable storage or the non-removable storage before or after execution by the processing unit.

It should be understood that the various techniques described herein may be implemented in connection with hardware or software or, where appropriate, with a combination thereof. Thus, the methods and apparatuses of the presently disclosed subject matter, or certain aspects or portions thereof, may take the form of program code (i.e., instructions) embodied in tangible media, such as floppy diskettes, CD-ROMs, hard drives, or any other machine-readable storage medium wherein, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an application programming interface (API), reusable controls, or the like. Such programs may be implemented in a high-level procedural or object-oriented programming language to communicate with a computer system. However, the program(s) can be implemented in assembly or machine language, if desired. In any case, the language may be a compiled or interpreted language, and it may be combined with hardware implementations.

It should be appreciated that any of the components or modules referred to with regards to any of the present embodiments discussed herein may be integrally or separately formed with one another. Further, redundant functions or structures of the components or modules may be implemented. Moreover, the various components may be communicated locally and/or remotely with any user/clinician/patient or machine/system/computer/processor.

Moreover, the various components may be in communication via wireless and/or hardwire or other desirable and available communication means, systems, and hardware. Moreover, various components and modules may be substituted with other modules or components that provide similar functions.

Machine Learning. In addition to the machine learning features described above, the analysis system can be implemented using one or more artificial intelligence and machine learning operations. The term “artificial intelligence” can include any technique that enables one or more computing devices or computing systems (i.e., a machine) to mimic human intelligence. Artificial intelligence (AI) includes but is not limited to knowledge bases, machine learning, representation learning, and deep learning. The term “machine learning” is defined herein to be a subset of AI that enables a machine to acquire knowledge by extracting patterns from raw data. Machine learning techniques include, but are not limited to, logistic regression, support vector machines (SVMs), decision trees, Naïve Bayes classifiers, and artificial neural networks. The term “representation learning” is defined herein to be a subset of machine learning that enables a machine to automatically discover representations needed for feature detection, prediction, or classification from raw data. Representation learning techniques include, but are not limited to, autoencoders and embeddings. The term “deep learning” is defined herein to be a subset of machine learning that enables a machine to automatically discover representations needed for feature detection, prediction, classification, etc., using layers of processing. Deep learning techniques include but are not limited to artificial neural networks or multilayer perceptron (MLP).

An artificial neural network (ANN) is a computing system including a plurality of interconnected neurons (e.g., also referred to as “nodes”). This disclosure contemplates that the nodes can be implemented using a computing device (e.g., a processing unit and memory as described herein). The nodes can be arranged in a plurality of layers, such as an input layer, an output layer, and optionally one or more hidden layers with different activation functions. An ANN having hidden layers can be referred to as a deep neural network or multilayer perceptron (MLP). Each node is connected to one or more other nodes in the ANN. For example, each layer is made of a plurality of nodes, where each node is connected to all nodes in the previous layer. The nodes in a given layer are not interconnected with one another, i.e., the nodes in a given layer function independently of one another. As used herein, nodes in the input layer receive data from outside of the ANN, nodes in the hidden layer(s) modify the data between the input and output layers, and nodes in the output layer provide the results. Each node is configured to receive an input, implement an activation function (e.g., binary step, linear, sigmoid, tanh, or rectified linear unit (ReLU) function), and provide an output in accordance with the activation function. Additionally, each node is associated with a respective weight. ANNs are trained with a dataset to maximize or minimize an objective function. In some implementations, the objective function is a cost function, which is a measure of the ANN's performance (e.g., error such as L1 or L2 loss) during training, and the training algorithm tunes the node weights and/or bias to minimize the cost function. This disclosure contemplates that any algorithm that finds the maximum or minimum of the objective function can be used for training the ANN. Training algorithms for ANNs include but are not limited to backpropagation. It should be understood that an artificial neural network is provided only as an example machine learning model. This disclosure contemplates that the machine learning model can be any supervised learning model, semi-supervised learning model, or unsupervised learning model. Optionally, the machine learning model is a deep learning model. Machine learning models are known in the art and are therefore not described in further detail herein.

A convolutional neural network (CNN) is a type of deep neural network that has been applied, for example, to image analysis applications. Unlike traditional neural networks, each layer in a CNN has a plurality of nodes arranged in three dimensions (width, height, depth). CNNs can include different types of layers, e.g., convolutional, pooling, and fully-connected (also referred to herein as “dense”) layers. A convolutional layer includes a set of filters and performs the bulk of the computations. A pooling layer is optionally inserted between convolutional layers to reduce the computational power and/or control overfitting (e.g., by downsampling). A fully-connected layer includes neurons, where each neuron is connected to all of the neurons in the previous layer. The layers are stacked similarly to traditional neural networks. GCNNs are CNNs that have been adapted to work on structured datasets such as graphs.

Other Supervised Learning Models. A logistic regression (LR) classifier is a supervised classification model that uses the logistic function to predict the probability of a target, which can be used for classification. LR classifiers are trained with a data set (also referred to herein as a “dataset”) to maximize or minimize an objective function, for example, a measure of the LR classifier's performance (e.g., an error such as L1 or L2 loss), during training. This disclosure contemplates that any algorithm that finds the minimum of the cost function can be used. LR classifiers are known in the art and are therefore not described in further detail herein.

A Naïve Bayes' (NB) classifier is a supervised classification model that is based on Bayes' Theorem, which assumes independence among features (i.e., the presence of one feature in a class is unrelated to the presence of any other features). NB classifiers are trained with a data set by computing the conditional probability distribution of each feature given a label and applying Bayes' Theorem to compute the conditional probability distribution of a label given an observation. NB classifiers are known in the art and are therefore not described in further detail herein.

A k-NN classifier is an unsupervised classification model that classifies new data points based on similarity measures (e.g., distance functions). The k-NN classifiers are trained with a data set (also referred to herein as a “dataset”) to maximize or minimize a measure of the k-NN classifier's performance during training. This disclosure contemplates any algorithm that finds the maximum or minimum. The k-NN classifiers are known in the art and are therefore not described in further detail herein.

A majority voting ensemble is a meta-classifier that combines a plurality of machine learning classifiers for classification via majority voting. In other words, the majority voting ensemble's final prediction (e.g., class label) is the one predicted most frequently by the member classification models. The majority voting ensembles are known in the art and are therefore not described in further detail herein.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another implementation includes from the one particular value and/or to the other particular value. Similarly, when values are expressed as approximations, by use of the antecedent “about,” it will be understood that the particular value forms another implementation. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal implementation. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific implementation or combination of implementations of the disclosed methods.

The following patents, applications and publications as listed below and throughout this document are hereby incorporated by reference in their entirety herein.
Anuprecthi, B., Gupta, A., Kannan, U., Tiwari, A. P., 2020. Optimization of flux mapping in-core detector locations in AHWR using clustering approach. Nucl. Eng. Des. 366, 110756.
Argaud, J-P., Bouriquet, B., De Caso, F., Gong, H., Maday, Y., Mula, O., 2018. Sensor placement in nuclear reactors based on the generalized empirical interpolation method. J. Comput. Phys. 363, 354370.
Bellman, R., 1952. On the theory of dynamic programming. Proc. Natl. Acad. Sci. 38 (8), 716-719. Bahuguna, S. K., Mukhopadhyay, S., Tiwari, A. P., 2023. Sensor position optimization for flux mapping in a nuclear reactor using compressed sensing. Ann. Nucl. Energy 183, 109588.
Berkooz, G., Holmes, P., Lumley, J. L., 1993. The proper orthogonal decomposition in the analysis of turbulent flows. Annu. Rev. Fluid Mech. 25 (1), 539-575.
Brockman, G., Cheung, V., Pettersson, L., Schneider, J. Schulman, Tang, J., Zaremba, W., 2016. Openai gym. arXiv preprint arXiv: 1606.01540.
Browne, C. B., Powley, E., Whitehouse, D., Lucas, S. M., Cowling, P. I., Rohlfshagen, P., Tavener, S., Perez, D., Samothrakis, S., Colton, S., 2012. A survey of Monte Carlo tree search methods, IEEE Trans. Comput. Intell.
Huang, M., Jin, S., Qin, G., 2012. Analysis and Comparison about In-core NeutronFlux Measurement System of AP1000 and EPR. Nucl. Electron. Detect. Technol. 32 (2), 161-164 (In Chinese).
Horelik, N., Herman, B., Forger, B., et al., 2013. Benchmark for Evaluation and Validation of Reactor Simulations (BEAVRS). M&C2013, Sun Valley, Idaho.
Hauer, E., Kononov, J., Allery, B., Griffith, M. S., 2002. Screening the road network for sites with promise. Transp. Res. Rec. 1784 (1), 27-32.
Liang, Y. C., Lec, H. P., Lim, S. P., Lin, W. Z., Lee, K. H., Wu, C. G 1237, 2002. Proper orthogonal decomposition and its applications-Part I: Theory. J. Sound Vib. 252 (3), 527-544.
Mishra, S., Modak, R. S., Ganesan, S., 2012. Selection of fuel channels for Thermal Power Measurement in 700 MWe Indian PHWR by evolutionary algorithm. Nucl. Eng. Des. 247, 116-122.
Mnih, V., Kavukcuoglu, K., Silver, D., Rusu, A. A., Veness, J., Bellemare, M. G., Graves, A., et al., 2015. Human-level control through deep reinforcement learning. Nature 518 (7540), 529-533.
Mnih, V., Badia, A. P., Mirza, M., Graves, A., Lillicrap, T., Harley, T., Silver, D., Kavukcuoglu, K., 2016. Asynchronous methods for deep reinforcement learning. In: Int. Conf. Mach. Learn., pp. 19281937. PMLR.
Nasr, M., Shokri, R., Houmansadr, A., 2019. Comprehensive privacy analysis of deep learning: Passive and active white-box inference attacks against centralized and federated learning. In: 2019 IEEE Symposium on Security and Privacy (SP), pp. 739-753. IEEE.
Oh, D. Y., No, H. C., 1994. Determination of the minimal number and optimal sensor location in a nuclear system with fixed in-core detectors. Nucl. Eng. Des. 152 (1-3), 197-212.
Sutton, R. S., Barto, A. G., 2018. Reinforcement learning: An introduction. MIT press. Terman, M. S., Kojouri, N. M., Khalafi, H., 2018. Optimal placement of fixed in-core detectors for Tehran Research Reactor using information theory. Prog. Nucl. Energy 106, 300-315.
Yellapu, V. S., Tiwari, A. P., Degweker, S. B., 2017. Application of data reconciliation for fault detection and isolation of in-core self-powered neutron detectors using iterative principal component test. Prog. Nucl. Energy 100, 326-343. https://doi.org/10. 1016/j.pnucenc.2017.04.017.
Lillicrap, T. P., Hunt, J. J., Pritzel, A., Heess, N., Erez, T., Tassa, Y., Silver, D., Wierstra, D., 2015. Continuous control with deep reinforcement learning, arXiv preprint arXiv: 1509.02971.
Schulman, J., Levine, S., Abbeel, P., Jordan, M., Moritz, P., 2015. Trust region policy optimization. In: Int. Conf. Mach. Learn., pp. 1889-1897.
Schulman, J., Wolski, F., Dhariwal, P., Radford, A., Klimov, O., 2017. Proximal policy optimization algorithms, arXiv preprint arXiv: 1707.06347.
Sivanandam, S. N., Deepa, S. N., 2008. Genetic algorithms. Springer Berlin Heidelberg.
Wang, Z., McBee, B., Iliescu, T., 2016. Approximate partitioned method of snapshots for POD. J. Comput. Appl. Math. 307, 374-384.
Anupreethi, B., Gupta, A., Kannan, U., Tiwari, A. P., 2020. Optimization of flux mapping in-core detector locations in AHWR using clustering approach. Nucl. Eng. Des. 366, 110756.
Hasselt, H. V., 2010. Double Q-learning. In: Proc. Adv. Neural Inf. Process. Syst., pp. 2613-2621.
Wiering, M. A., Otterlo, M. V., 2012. Reinforcement learning. Adapt. Learn. Optim. 12 (3), 729.
Williams, R. J., 1992. Simple statistical gradient-following algorithms for connectionist reinforcement learning. In: Reinforcement learning, pp. 5-32.
Li, Zhuo, Yu Ma, Liangzhi Cao, and Hongchun Wu., 2019. Proper orthogonal decomposition based online power-distribution reconstruction method. Ann. Nucl. Energy 131, 417-424.
Romano, P. K., Horelik, N. E., Herman, B. R., Nelson, A. G., Forget, B., Smith, K., 2015. OpenMC: A state-of-the-art Monte Carlo code for research and development. Ann. Nucl. Energy 82, 90-97.
Raffin, A., Hill, A., Gleave, A., Kanervisto, A., Ernestus, M., Dormann, N., 2021. Stable-baselines3: Reliable reinforcement learning implementations. J. Mach. Learn. Res. 22 (1), 12348-12355.
Radaideh, M. I., Wolverton, I., Joseph, J., Tusar, J. J., Otgonbaatar, U., Roy, N., Forget, B., Shirvan, K., 2021. Physics-informed reinforcement learning optimization of nuclear assembly design. Nucl. Eng. Des. 372, 110966.
Zameer, H., Wang, Y., Yasmeen, H., Mubarak, S., 2022. Green innovation as a mediator in the impact of business analytics and environmental orientation on green competitive advantage. Manag. Decis. 60 (2), 488-507.

What is claimed:

1. A computer-implemented method for optimizing nuclear reactor detector placement, the method comprising:
receiving a nuclear reactor model, wherein the nuclear reactor model comprises a model of (i) at least one radiation source or flux and (ii) a plurality of candidate detector positions;
constructing a Markov Decision Process (MDP) wherein the MDP comprises a process for selecting detector placements and comparing a simulated flux distribution and a reconstructed flux distribution for simulated detector placements;
determining a reward function, wherein the reward function is configured to evaluate a power reconstruction error between the simulated flux distribution and the reconstructed flux distribution;
selecting a first arrangement of detectors based on the MDP and performing a first evaluation of the first arrangement of detectors by the reward function;
selecting a second arrangement of detectors based on the MDP and performing a second evaluation of the second arrangement of detectors by the reward function;
determining an optimized configuration of detectors for the nuclear reactor model based on the first evaluation and the second evaluation, wherein the optimized configuration of detectors comprises an assignment of detectors to at least one of the plurality of candidate detector positions.

2. The computer-implemented method of claim 1, wherein determining an optimized configuration of detectors comprises iteratively selecting a plurality of detector placements.

3. The computer-implemented method of claim 1, wherein determining the optimized configuration of detectors comprises applying a reinforcement learning (RL) algorithm.

4. The computer-implemented method of claim 3, wherein the RL comprises Proper Orthogonal Decomposition (POD) based power reconstruction function paired with a reward function based on the power reconstruction error.

5. The computer-implemented method of claim 3, wherein the RL comprises at least one of Proximal Policy Optimization, Deep Q-Network (DQN), Advantage Actor-Critic (A2C), and Monte Carlo Tree Search (MCTS).

6. The computer-implemented method of claim 1, wherein the second detector placement is determined by a trained agent configured to update the detector placement.

7. The computer-implemented method of claim 1, wherein the nuclear reactor model comprises a model of a pressurized water reactor (PWR).

8. A non-transitory computer readable medium having instructions stored thereon, wherein execution of the instructions by a processor, causes the processor to:
receive a nuclear reactor model, wherein the nuclear reactor model comprises a model of (i) at least one radiation source or flux and (ii) a plurality of candidate detector positions;
construct a Markov Decision Process (MDP) wherein the MDP comprises a process for selecting detector placements and comparing simulated flux distribution and a reconstructed flux distribution for simulated detector placements;
determine a reward function, wherein the reward function is configured to evaluate a power reconstruction error between the simulated flux distribution and the reconstructed flux distribution;
select a first arrangement of detectors based on the MDP and performing a first evaluation of the first arrangement of detectors by the reward function;
select a second arrangement of detectors based on the MDP and performing a second evaluation of the second arrangement of detectors by the reward function;
determine an optimized configuration of detectors for the nuclear reactor model based on the first evaluation and the second evaluation, wherein the optimized configuration of detectors comprises an assignment of detectors to at least one of the plurality of candidate detector positions.

9. The non-transitory computer readable medium of claim 8, wherein determining an optimized configuration of detectors comprises iteratively selecting a plurality of detector placements.

10. The non-transitory computer readable medium of claim 8, wherein determining the optimized configuration of detectors comprises applying a reinforcement learning (RL) algorithm.

11. The non-transitory computer readable medium of claim 10, wherein the RL comprises Proper Orthogonal Decomposition (POD) based power reconstruction function paired with a reward function based on the power reconstruction error.

12. The non-transitory computer readable medium of claim 10, wherein the RL comprises at least one of Proximal Policy Optimization, Deep Q-Network (DQN), Advantage Actor-Critic (A2C), and Monte Carlo Tree Search (MCTS).

13. The non-transitory computer readable medium of claim 8, wherein the second detector placement is determined by a trained agent configured to update the detector placement.

14. The non-transitory computer readable medium of claim 8, wherein the nuclear reactor model comprises a model of a pressurized water reactor (PWR).

15. A nuclear reactor system comprising:
a reactor; and
a plurality of detectors configured to monitor the reactor, the plurality of detectors being positioned at locations determined by:
receiving a nuclear reactor model, wherein the nuclear reactor model comprises a model of (i) at least one radiation source or flux and (ii) a plurality of candidate detector positions;
constructing a Markov Decision Process (MDP) wherein the MDP comprises a process for selecting detector placements and comparing simulated flux distribution and a reconstructed flux distribution for simulated detector placements;
determining a reward function, wherein the reward function is configured to evaluate a power reconstruction error between the simulated flux distribution and the reconstructed flux distribution;
selecting a first arrangement of detectors based on the MDP and performing a first evaluation of the first arrangement of detectors by the reward function;
selecting a second arrangement of detectors based on the MDP and performing a second evaluation of the second arrangement of detectors by the reward function;
determining an optimized configuration of detectors for the nuclear reactor model based on the first evaluation and the second evaluation, wherein the optimized configuration of detectors comprises an assignment of detectors to at least one of the plurality of candidate detector positions.

16. The nuclear reactor system of claim 15, wherein determining an optimized configuration of detectors comprises iteratively selecting a plurality of detector placements.

17. The nuclear reactor system of claim 15, wherein determining the optimized configuration of detectors comprises applying a reinforcement learning (RL) algorithm.

18. The nuclear reactor system of claim 17, wherein the RL comprises Proper Orthogonal Decomposition (POD) based power reconstruction function paired with a reward function based on the power reconstruction error.

19. The nuclear reactor system of claim 17, wherein the RL comprises at least one of Proximal Policy Optimization, Deep Q-Network (DQN), Advantage Actor-Critic (A2C), and Monte Carlo Tree Search (MCTS).

20. The nuclear reactor system of claim 15, wherein the second detector placement is determined by a trained agent configured to update the detector placement.
